(19) United States
(12) Patent Application Publication
(10) Pub. No.: US 2014/0137939 A1
(43) Pub. Date: May 22, 2014

(54) SOLAR-CELL MODULE AND MANUFACTURING METHOD THEREFOR

(71) Applicant: FUJIFILM CORPORATION, (US)

(72) Inventor: Akio HIGASHI, Kanagawa (JP)

(73) Assignee: FUJIFILM CORPORATION, Tokyo (JP)

(21) Appl. No.: 13/870,618

(22) Filed: Apr. 25, 2013

Related U.S. Application Data
(63) Continuation of application No. PCT/JP2011/073930, filed on Oct. 18, 2011.

(30) Foreign Application Priority Data
Oct. 28, 2010 (JP) 2010-241938
Mar. 24, 2011 (JP) 2011-065771

(51) Int. Cl. H01L 31/048; H01L 31/18

(52) U.S. Cl. CPC H01L 31/0481; H01L 31/18
USPC 136/259; 438/69

(57) ABSTRACT

A solar-cell submodule sealed by an adhesive filler. A water-vapor-barrier film, a first adhesive filler layer, and a front-surface protection layer are layered on the front surface side of the solar-cell submodule, and a second adhesive filler layer and a back surface protection layer are layered on the back surface side of the solar cell submodule. A light-absorbing layer in the solar cell submodule comprises a CIGS film, and of the front surface protection layer and back surface protection layer, at least the front surface protection layer includes a plastic sheet. The plastic sheet has a heat-shrinkage ratio of not more than 0.04%.

### BACKGROUND OF THE INVENTION

The present invention relates to a solar cell module which uses CIGS for a photoelectric conversion layer, and a method of manufacturing the same, and in particular, to a solar cell module which includes a front surface protection layer having high mechanical strength and impact strength, and is lightweight and low-cost, and a method of manufacturing the same.

In a solar cell, multiple solar cells having a laminated structure in which a semiconductor light absorbing layer generating current by light absorption sandwiched between a lower electrode (back surface electrode) and an upper electrode (transparent electrode) are connected in series together to constitute a semiconductor circuit, and the semiconductor circuit is formed on the substrate. The solar cell having this configuration is attracting attention as clean energy. For this reason, studies on the solar cell are actively conducted, and improvements are attempted from various viewpoints.

As an example, a solar cell is vulnerable to moisture, and if moisture enters, characteristics, such as conversion efficiency, are deteriorated. In particular, in a chalcopyrite solar cell which uses CuInSe₂ (CIS) having a chalcopyrite structure containing a Ib group element, a IIIb group element, and a VIb group element, or Cu(In,Ga)Se₂ (CIGS) obtained by dissolving Ga in CIS as a light absorbing layer, since a ZnO film or the like is used as a transparent electrode, the transparent electrode is changed in quality due to entering of moisture. Accordingly, the electric resistance of the transparent electrode increases, and conversion efficiency is significantly lowered.

However, as well known in the art, in many cases, a solar cell is often installed in the outdoors such as an outdoor mount, a roof or a rooftop. For this reason, there are various suggestions for improving waterproof performance of a solar cell module (JP 2007-123725 A, JP 2001-196614 A, JP 2009-194114 A, JP 10-190034 A, JP 2006-165434 A, JP 2006-120972 A, WO 2006/106844, JP 3530595 B, and JP 2011-12243 A).

JP 2007-123725 A describes a CIS-based thin-film solar cell module. This CIS-based thin-film solar cell module includes a CIS-based thin-film solar cell circuit or a CIS-based thin-film solar cell submodule in which a plurality of CIS-based thin-film solar cell devices composed of an alkali barrier layer, a metal back surface electrode layer, a light absorbing layer, a buffer layer, and a window layer laminated on a glass substrate in this order are electrically connected together by a conductive pattern and a cover glass made of a half-tempered super white glass or the like bonded to the CIS-based thin-film solar cell circuit or the CIS-based thin-film solar cell submodule using a thermally polymerized and cross-linked ethylene-vinyl acetate (hereinafter, referred to as EVA) resin film or sheet as an adhesive.

JP 2001-196614 A describes a solar cell module in which a front surface protection layer, a filler layer made of a resin layer having at least transparency and cushion performance and further having heat resistance and excellent non-deterioration and non-degradation against action of heat, a solar cell device, a filler layer, and a back surface protection layer are laminated in order, one or more layers of an antifouling layer, an ultraviolet shielding layer, and a weather-resistant layer are further laminated on the back surface protection layer or between the layers, and these layers are integrated as a single body.

JP 2001-196614 A describes a front surface protection layer or a back surface protection layer made of a vapor-deposited film in which an inorganic oxide is vapor-deposited on a base material film.

JP 2009-194114 A describes a solar cell module having a solar cell submodule which receives sunlight and the like and generates power, and a seal material which seals the entire solar cell submodule. The seal material is a protection sheet which seals the solar cell submodule to prevent the inflow of moisture from the outside, and has a light receiving surface seal material which covers the light receiving surface of the solar cell module and a rear surface seal material which covers the opposite surface to the light receiving surface.

The light receiving surface seal material and the rear surface seal material have a planar size greater than the planar size of the solar cell submodule, and can cover the entire plane of the solar cell submodule.

The light receiving surface seal material and the rear surface seal material are made of fluorinated resin, and preferably have a thickness of about 50 to 200 μm from the viewpoint of durability and reduction in weight in use.

JP 10-190034 A describes a solar cell panel having a transparent synthetic resin substrate, a plurality of solar cells which are arranged on the substrate with a clearance portion such that the light receiving surface faces the substrate, interconnects which are wired in the clearance portion on the substrate to connect the electrodes of the solar cells together, and a synthetic resin clad which is bonded to the clearance portion of the substrate to cover the rear surfaces of the cells.

JP 10-190034 A describes that a polycarbonate resin plate, a methyl methacrylate resin plate, or a laminated plate of polycarbonate resin and methyl methacrylate resin is used for a synthetic resin substrate.

JP 2006-165434 A describes a solar cell module in which a filler and a solar cell device are sealed by a front surface protection layer and a back surface protection layer for sealing the solar cell device, and spacers on both sides. In this solar cell module, in order to satisfy the functions, such as heat resistance, weather resistance, and moisture-proof performance, a front surface protection sheet in which a resin film, such as a PET film, acryl, or polycarbonate, is laminated on the inner surface of a cyclic olefin polymer film or a cyclic olefin copolymer film, through an adhesive is used as a front surface protection sheet of the solar cell module.

JP 2006-120972 A describes a solar cell module in which at least a vapor-deposited thin-film layer of an inorganic oxide is laminated to form a transparent vapor-deposited film layer, a solar cell front surface protection sheet is made of a laminate having a polycarbonate film layer laminated on the vapor-deposited thin-film layer side of the transparent vapor-deposited film layer, and the solar cell front surface protection sheet is used for a transparent film layer.

In JP 2006-120972 A, gas barrier performance is exhibited with the transparent vapor-deposited film layer in which the vapor-deposited thin-film layer of the inorganic oxide is laminated.

WO 2006/106844 describes a solar cell module having a back surface protection sheet for use in a solar cell. The back surface protection sheet has an unstretched transparent polybutylene terephthalate film, an adhesive layer arranged on the unstretched transparent polybutylene terephthalate film, and a gas barrier vapor-deposited film in which a vapor-deposited layer of an inorganic oxide is vapor-deposited on a base material. The back surface protection sheet for solar cell in which the gas barrier vapor-deposited film is arranged on the solar cell device side is used, and the solar cell module is unitized such that the surface of the unstretched polybutylene terephthalate film layer of the back surface protection sheet for solar cell turns outward.

JP 3530595 B describes a solar cell module in which a photovoltaic device having a semiconductor photoactive layer as a light conversion member is covered with a filler. In this solar cell module, a hard resin layer made of resin having Shore hardness equal to or greater than D50, an adhesive layer of a thermoplastic resin combined with an ultraviolet absorber, and an outermost layer are laminated on the light receiving surface of the photovoltaic device in this order from the light receiving surface. The thickness of the hard resin layer is equal to or greater than 25 μm and equal to or smaller than 200 μm, and the hard resin layer is made of a material selected from polycarbonate resin and polyester resin. Resin which forms the outermost layer is fluorinated resin, for example, ETFE.

JP 2011-12243 A describes an ethylene-based resin composition which contains a modified form of an ethylene-based polymer (A) simultaneously satisfying the following requirements a) to e) with a radical polymerizable unsaturated compound (B1) comprising an ethylenic unsaturated silane compound and a radical polymerizable unsaturated compound (B2) comprising at least one compound selected from a hydroxyl group containing ethylenic unsaturated compound, an amine group containing ethylenic unsaturated compound, an epoxy group containing ethylenic unsaturated compound, an aromatic vinyl compound, an unsaturated carboxylic acid or a derivative thereof, a vinylester compound, a vinyl chloride, and a carbodiimide compound.

a) a density is 900 to 940 kg/m³

b) a melting peak based on DSC is 90 to 125° C.

c) a melt flow rate (MFR2) measured at 190° C. and 2.16 kg load based on JISK-6721 is 0.1 to 100 g/10 minutes

d) Mw/Mn is 1.2 to 3.5

e) a metal residue is 0.1 to 50 ppm

JP 2011-12243 A describes an ethylene-based resin composition which contains (i) a modified form selected from a modified form (1) of an ethylene-based polymer (A) with a radical polymerizable unsaturated compound (B1) or a modified form (3) of a mixture of an ethylene-based polymer (A) and an ethylene.α-olefin copolymer (C) with a radical polymerizable unsaturated compound (B1), and (ii) a modified form selected from a modified form (2) of an ethylene-based polymer (A) with a radical polymerizable unsaturated compound (B2) or a modified form (4) of a mixture of an ethylene-based polymer (A) and an ethylene.α-olefin copolymer (C) with a radical polymerizable unsaturated compound (B2).

The ethylene-based resin composition of JP 2011-12243 A is used for a solar cell seal sheet utilized in a solar cell module. JP 2011-12243 A describes, as the configuration of the solar cell module, the configuration of solar cell module protection sheet (front surface protection sheet)/solar cell seal sheet/solar cell device/solar cell seal sheet/solar cell module protection sheet (back surface protection sheet).

In JP 2011-12243 A, examples of a solar cell module front surface protection sheet which is suitably used for a solar cell module include a glass substrate, and the like, in addition to a resin film made of polyester resin, fluorinated resin, acrylic resin, a cyclic olefin (co)polymer, or an ethylene-vinyl acetate copolymer.

As described above, in JP 2007-123725 A, the most common tempered super white glass is provided as the front surface protection layer, and thereby impact strength and waterproof performance are kept. However, the thickness of glass to be generally used is 3 mm, and when the thickness is 3 mm, the weight becomes 7.5 kg/m². For this reason, in JP 2007-123725 A, there is difficulty in achieving reduction in weight.

Meanwhile, in JP 2001-196614 A, JP 2009-194114 A, JP 10-190034 A, JP 2006-165434 A, JP 2006-120972 A, WO 2006/106844, JP 3530595 B, and JP 2011-12243 A, a front surface protection layer is made of a resin film or a resin sheet, instead of glass. In JP 2001-196614 A, while examples of resin having transparency, cushion performance, heat resistance, and the like include polyethylene, polypropylene, a fluorine-based resin, polyolefin, acrylic, and the like, with these, it is impossible to realize waterproof performance which is required for a CIGS solar cell.

In JP 2009-194114 A, while a fluorine-based film having a thickness of 50 to 200 μm is used for the light receiving surface seal material and the rear surface seal material, there is a problem in that mechanical strength and impact strength are weak. Furthermore, since there is no moisture vapor barrier film, there is also a problem in that moisture resistance and long-term reliability are not obtained with respect to a CIGS solar cell.

In JP 10-190034 A, while the front surface protection layer is made of a synthetic resin substrate in which both polycarbonate and methacrylate are laminated, no moisture vapor barrier layer is included in the overall structure, and there is a problem in that moisture resistance and long-term reliability are not obtained with respect to a solar cell using a CIGS film for a light absorbing layer (hereinafter, this solar cell is referred to as a CIGS solar cell). In addition, at the time of manufacturing of the module, in a vacuum lamination step, the synthetic resin substrate heat-shrinks, and failure that the module is curved occurs.

In JP 2006-165434 A, while the front surface protection sheet on the light receiving side has a structure in which the resin film, such as PET, acryl, or polycarbonate, is laminated on the inner surface of the cyclic olefin polymer film through the adhesive, if the front surface protection sheet is made of an olefin polymer film, impact strength is weak, and a constituent material having moisture vapor barrier performance is required for a CIGS solar cell.

While JP 2006-120972 A describes the transparent vapor-deposited film layer which has gas barrier performance and in which the vapor-deposited thin-film layer of the inorganic oxide is laminated, and WO 2006/106844 describes the gas barrier vapor-deposited film, there is a problem in that, under a high-temperature and high-humidity environment, separation occurs due to the difference in heat expansion and heat shrinkage between the members or a cavity is partially generated, and moisture infiltrates the cavity, causing significant characteristic deterioration.

In the solar cell module of JP 3530595 B, the outermost ETFE, the adhesive layer, and the hard resin layer are laminated from the light receiving side, and the hard resin layer is made of polycarbonate, ester resin, or the like to have a thickness of 25 to 200 μm. However, in the solar cell module of JP 3530595 B, since the hard resin layer is thin, sufficient impact resistance is not obtained. In addition, in the solar cell module of JP 3530595 B, since no moisture vapor barrier layer is provided, there is a problem in that sufficient moisture resistance is not obtained.

While JP 2011-12243 A discloses the ethylene-based resin composition which contains the ethylene.α-olefin copolymer, as the solar cell module front surface protection sheet, a resin film made of polyester resin, fluororesin, acrylic resin, a cyclic olefin (co)polymer, an ethylene-vinyl acetate copolymer, or the like may be used. For this reason, there is a problem in that sufficient impact resistance is not obtained.

The characteristics to be required for a solar cell module having long-term reliability over 20 to 30 years are that conversion efficiency of the solar cell itself is of course high, and that weather resistance, heat resistance, flame resistance, water resistance, moisture resistance, wind pressure resistance, hailstorm fall resistance, and all other characteristics are excellent. In addition, it is necessary to reduce the cost of the solar cell module or the panel itself and also to reduce the cost of construction for installation. In a heavy solar cell panel or a solar cell module which uses a tempered glass of the related art for a front surface protection layer, the cost of reinforcement work or the like is spent so as to fix the solar cell panel or the solar cell module at a general housing or a slate roof. For this reason, there is a demand for realizing a solar cell module which is lightweight and has excellent performance so as to reduce the total cost.

### SUMMARY OF THE INVENTION

The invention has been accomplished in order to solve the problems inherent in the related art, and an object of the invention is to provide a solar cell module which includes a front surface protection layer having high mechanical strength and impact strength, and is lightweight and low-cost, and a method of manufacturing the same.

To solve the above problems, a first aspect of the present invention provides a solar cell module in which a moisture vapor barrier film, a first adhesive filler layer, and a front surface protection layer are laminated on the front surface of a solar cell submodule sealed by an adhesive filler, and a second adhesive filler layer and a back surface protection layer are laminated on a back surface of the solar cell submodule, wherein the solar cell submodule has a light absorbing layer which is made of a CIGS (copper indium gallium selenide) film, and wherein, of the front surface protection layer and the back surface protection layer, at least the front surface protection layer is made of a plastic sheet, and the plastic sheet has a thermal shrinkage ratio equal to or smaller than 0.04%.

In this case, the plastic sheet is preferably made of polycarbonate resin or acrylic resin, and the thickness of the plastic sheet is 0.5 to 2.5 mm.

Further, an intermediate seal material for moisture vapor infiltration prevention is preferably provided within 5 to 30 mm from an edge portion of the back surface protection layer.

Further, a frame member is preferably in the edge portion, the frame member including a seal material provided inside and an outer frame material provided outside, wherein the seal material is made of butyl rubber or silicone resin, and the outer frame material is made of an aluminum frame or a metal foil tape.

A substrate which is used in the solar cell submodule is preferably an aluminum, a clad material of stainless steel, a clad material of aluminum, or a clad material of aluminum and stainless steel.

The intermediate seal material is preferably made of butyl rubber, polyisoprene, polyisobutylene, or isoprene.

A fluorine-based transparent resin film is preferably provided on the front surface protection layer.

A second aspect of the invention provides a method of manufacturing a solar cell module in which a moisture vapor barrier film, a first adhesive filler layer, and a front surface protection layer are laminated on the front surface of a solar cell submodule sealed by an adhesive filler, and a second adhesive filler layer and a back surface protection layer are laminated on the back surface of the solar cell submodule, wherein the solar cell submodule has a light absorbing layer which is made of a CIGS (Copper indium gallium selenide) film, of the front surface protection layer and the back surface protection layer, at least the front surface protection layer is made of a plastic sheet, and the method comprising the steps of: performing heat treatment on the plastic sheet at temperature of 100 to 140° C. in advance; laminating and arranging the adhesive filler, the moisture vapor barrier film, the first adhesive filler layer, and the plastic sheet subjected to the heat treatment which serves as the front surface protection layer on the front surface of the solar cell submodule, and laminating and arranging the second adhesive filler layer and the back surface protection layer on the back surface of the solar cell submodule; and performing vacuum lamination in a state where the plurality of layers are laminated and arranged to produce a laminated structure.

In this case, in the lamination and arrangement step, an intermediate seal material for moisture vapor infiltration prevention is preferably arranged within 5 to 30 mm from an edge portion of the back surface protection layer.

Preferably, the method further comprises a step of providing a frame member with a seal material provided inside and an outer frame material provided outside in the edge portion of the laminated structure after the vacuum lamination step.

Preferably, the plastic sheet is made of polycarbonate resin or acrylic resin, and a thickness of the plastic sheet is 0.5 to 2.5 mm.

In the lamination and arrangement step, a fluorine-based transparent resin film is preferably arranged on the plastic sheet.

A third aspect of the invention provides a method of manufacturing a solar cell module in which an adhesive filler, a moisture vapor barrier film, a first adhesive filler layer, and a front surface protection layer are laminated on the front surface of a solar cell submodule, and a second adhesive filler layer and a back surface protection layer are laminated on the back surface of the solar cell submodule, wherein the solar cell submodule has a structure in which a light absorbing layer made of a CIGS (copper indium gallium selenide) film is formed on a substrate in which an anodized aluminum film is formed on the front surface of a metal sheet, wherein, of the front surface protection layer and the back surface protection layer, at least the front surface protection layer is made of a plastic sheet, the method comprising the steps of: performing heat treatment on the plastic sheet in advance; performing corona treatment on a surface coming in contact with the first adhesive filler layer of the plastic sheet; coating the corona-treated surface of the plastic sheet with a primer; laminating and arranging the adhesive filler, the moisture vapor barrier film, and the first adhesive filler layer on the front surface of the solar cell submodule, laminating and arranging the plastic sheet, which is subjected to the heat treatment and the corona treatment and which is coated with the primer, such that the surface with the primer coated faces the first adhesive filler layer, and laminating and arranging the second adhesive filler layer and the back surface protection layer on the back surface of the solar cell submodule; and performing vacuum lamination in a state where the plurality of layers are laminated and arranged to produce a laminated structure.

In this case, the plastic sheet is preferably made of polycarbonate resin or acrylic resin, and the thickness of the plastic sheet is 0.5 to 2.0 mm. In this case, the plastic sheet is preferably composed of polycarbonate resin.

The heat treatment step of the plastic sheet is preferably executed at temperature of 100 to 140° C.

Preferably, the first adhesive filler layer is made of thermoplastic olefin-based polymer resin or thermoplastic polyurethane resin, and the temperature of the vacuum lamination step is 120 to 145° C.

The plastic sheet preferably has an embossing structure on the surface which comes in contact with the first adhesive filler layer.

The lamination and arrangement step preferably includes a step of arranging an intermediate seal material for moisture vapor infiltration prevention within 5 to 30 mm from an edge portion of the back surface protection layer.

Preferably, the lamination and arrangement step includes the step of arranging an edge seal material for moisture vapor infiltration prevention in the edge portions of the front surface protection layer and the back surface protection layer, and laminating and arranging the solar cell submodule, the adhesive filler, the moisture vapor barrier film, the first adhesive filler layer, the plastic sheet, and the second adhesive filler layer inside the edge seal material.

The method preferably further comprises a step of providing a frame member equipped with a seal material inside an outer frame material in the edge portion of the laminated structure after the vacuum lamination step.

According to the first aspect of the invention, the plastic sheet having a thermal shrinkage ratio equal to or smaller than 0.04% is used for the front surface protection layer, whereby mechanical strength and impact strength, such as wind pressure resistance and hailstorm fall resistance, can be equal to or greater than those of the tempered super white glass. If the thickness is identical, the plastic sheet has a density of 1.1 to 1.2 g/cm³ compared with 2.5 g/cm³, the density of glass, and thus the mass can be equal to or smaller than 50%.

In general, while the thickness of the tempered super white glass is 3 mm or 3.2 mm, by reducing the thickness of the front surface protection layer to as thin as 1 to 2 mm, the mass per unit area can be 1.2 to 2.4 kg/m². In this case, it is possible to reduce the weight up to 16 to 32% of that of the tempered super white glass.

While moisture or moisture vapor may be diffused from the front surface or the end surface (edge portion) of the solar cell module and cause defects, such as performance deterioration and electric wire corrosion, it is possible to more reliably suppress defects, such as performance deterioration and electric wire corrosion, due to moisture or moisture vapor by providing the moisture vapor barrier film on the front surface side, and the intermediate seal material, the edge seal material or providing the frame member on the end surface (edge portion). Even if moisture enters, it is possible to prevent moisture from reaching the transparent electrode of the solar cell or the like.

In this way, according to the invention, it is possible to realize a solar cell module which is capable of preventing infiltration of moisture into the solar cell module, and exhibiting stable performance and being stably used over a long period.

In this way, according to the first aspect of the invention, it is possible to realize a solar cell module which is capable of preventing infiltration of moisture into the solar cell module, and exhibiting stable performance and being stably used over a long period.

With the method of manufacturing a solar cell module according to the second aspect of the invention, it is possible to suitably manufacture the solar cell module of the first aspect having excellent characteristics.

Moreover, with the method of manufacturing a solar cell module according to the second aspect of the invention, the plastic sheet forming the front surface protection layer is subjected to the heat treatment at temperature 100 to 140° C. in advance, whereby the occurrence of curvature in the vacuum lamination step is suppressed.

When a plastic sheet is a constituent material, since the coefficient of linear expansion is large, and adhesiveness between the plastic sheet and the adhesive filler layer is very bad, there is a major problem in that the solar cell module is curved with a temperature rise, separation occurs between the constituent layers of the solar cell, or the like. For this reason, selection of constituent materials and improvement of adhesiveness are required. With the method of manufacturing a solar cell module according to the third aspect of the invention, the constituent materials of the solar cell module are appropriately selected, whereby it is possible to manufacture a solar cell module while improving adhesiveness and suppressing curvature, separation, and the like.

At least the surface of the adhesive filler layer side of the front surface protection layer has an embossing structure, whereby it is possible to improve adhesiveness of the front surface protection layer by an anchor effect.

With the method of manufacturing a solar cell module according to the third aspect of the invention, for example, it is possible to suitably manufacture a solar cell module which has excellent characteristics similar to the above-mentioned first aspect.

### BRIEF DESCRIPTION OF THE DRAWINGS

FIG. 1A is a schematic sectional view showing a solar cell module according to a first embodiment of the invention, and FIG. 1B is a schematic sectional view showing the arrangement state of respective members before vacuum lamination of the solar cell module of FIG. 1A.

FIG. 2 is a graph showing the relationship between the thickness of a polycarbonate sheet, and the shrinkage factor and the amount of curvature.

FIG. 3 is a schematic sectional view showing an example of a solar cell submodule which is used in the solar cell module according to the first embodiment of the invention.

FIG. 4 is a schematic sectional view showing the arrangement state of respective members before vacuum lamination of a solar cell module according to a second embodiment of the invention.

FIG. 5 is a schematic sectional view showing the arrangement state of respective members before vacuum lamination of a solar cell module according to a third embodiment of the invention.

FIG. 6A is a schematic sectional view showing the arrangement state of respective members before vacuum lamination of a solar cell module according to a fourth embodiment of the invention, and FIG. 6B is a schematic sectional view showing the solar cell module according to the fourth embodiment of the invention.

FIG. 7A is a schematic sectional view showing the arrangement state of respective members before vacuum lamination of a solar cell module according to a fifth embodiment of the invention, and FIG. 7B is a schematic sectional view showing the solar cell module according to the fifth embodiment of the invention.

FIG. 8A is a schematic sectional view showing the arrangement state of respective members before vacuum lamination of a solar cell module according to a sixth embodiment of the invention, and FIG. 8B is a schematic sectional view showing the solar cell module according to the sixth embodiment of the invention.

FIG. 9 is a schematic sectional view showing a first solar cell module of the related art.

FIG. 10 is a schematic sectional view showing a second solar cell module of the related art.

FIG. 11 is a schematic sectional view showing a third solar cell module of the related art.

FIG. 12 is a schematic sectional view showing a fourth solar cell module of the related art.

### DETAILED DESCRIPTION OF THE INVENTION

Hereinafter, a solar cell module and a method of manufacturing the same of the invention will be described in detail on the basis of preferred embodiments shown in the accompanying drawings.

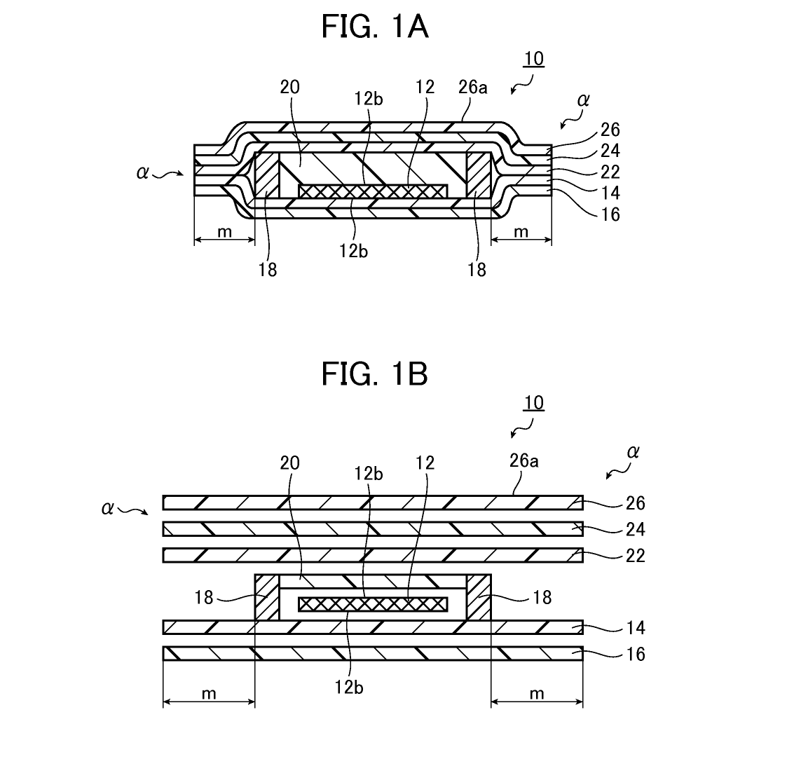

FIG. 1A is a schematic sectional view showing a solar cell module according to a first embodiment of the invention, and FIG. 1B is a schematic sectional view showing the arrangement state of respective members before vacuum lamination of the solar cell module of FIG. 1A.

As shown in FIG. 1A, a solar cell module 10 has a solar cell submodule 12 which is sealed by an adhesive filler 20 and a second adhesive filler layer 14. An intermediate seal material 18 is provided in the periphery of the adhesive filler 20. The intermediate seal material 18 is provided at a distance m from an edge portion α of the solar cell module 10, that is, inside the solar cell module 10.

The second adhesive filler layer 14 is provided on a back surface 12b of the solar cell submodule 12, and a back sheet (back surface protection layer) 16 is provided below the second adhesive filler layer 14.

A moisture vapor barrier film 22 is provided on a front surface 12a of the solar cell submodule 12. A first adhesive filler layer 24 is provided on the moisture vapor barrier film 22, and a front surface protection layer 26 is provided on the first adhesive filler layer 24.

In the solar cell module 10, the second adhesive filler layer 14, the back sheet 16, the moisture vapor barrier film 22, the first adhesive filler layer 24, and the front surface protection layer 26 are bonded together in the edge portion α.

In the solar cell module 10, as shown in FIG. 1B, the intermediate seal material 18 is provided in the periphery of the solar cell submodule 12, and the adhesive filler 20 is arranged so as to close the opening of the intermediate seal material 18. The second adhesive filler layer 14 and the back sheet 16 are laminated and arranged on the back surface 12b of the solar cell submodule 12.

The moisture vapor barrier film 22, the first adhesive filler layer 24, and the front surface protection layer 26 are laminated and arranged on the adhesive filler 20.

In this case, the intermediate seal material 18 is arranged at a distance m, for example, within 5 to 30 mm, from the edge portion α of the respective members.

In a state where the respective members are laminated and arranged as shown in FIG. 1B, for example, vacuum lamination is performed using a vacuum laminator having lifting means, an impingement plate, and heating means under the conditions of, for example, temperature of 130 to 140° C. and vacuum/press/retention of 15 to 30 minutes in total, whereby the solar cell module 10 shown in FIG. 1A can be produced.

In this embodiment, a fluorine-based transparent resin film described below may be laminated and arranged on a front surface 26a of the front surface protection layer 26, and vacuum lamination may be performed in this state to produce a solar cell module.

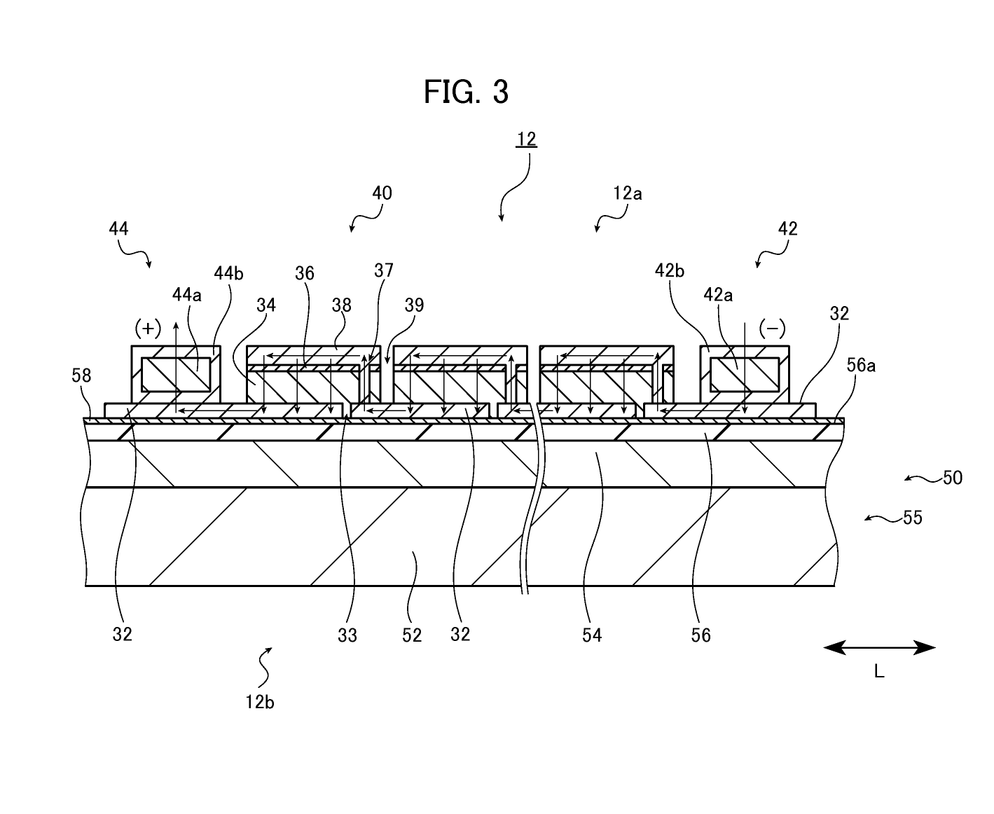

In the solar cell module 10 shown in FIG. 1A, as shown in FIG. 3, the solar cell submodule 12 is a laminated structure of solar cells 40 serving as photoelectric conversion devices. A single solar cell 40 is included in the solar cell submodule. A specific example of the solar cell submodule 12 will be described below in detail.

The adhesive filler 20 seals the solar cell submodule 12. For the adhesive filler 20, for example, EVA (ethylene-vinyl acetate), PVB (polyvinyl butyral), PE (polyethylene), an olefin-base adhesive, or the like may be used. In addition to these, various materials which are used as a seal material in a known solar cell module may be used. Thermoplastic olefin-based polymer resin and thermoplastic polyurethane resin have excellent adhesiveness, and are thus preferably used as the adhesive filler 20.

In order to improve adhesiveness, a primer may be applied to a plastic sheet or an adherend in advance, or so-called corona treatment in which the surface of a plastic sheet is exposed to the corona discharge atmosphere may be performed, thereby improving adhesiveness by the adhesive filler layer.

The intermediate seal material 18 is provided so as to suppress moisture infiltration from the adhesive filler 20 into the solar cell submodule 12. The intermediate seal material 18 is provided at a distance m from the edge portion α of the solar cell module 10. The distance m is preferably 5 to 30 mm such that manufacturing variations and module efficiency are kept. The width of the intermediate seal material 18 is preferably 5 to 20 mm.

For the intermediate seal material 18, for example, butyl rubber, polyisoprene, polyisobutylene, isoprene, or the like having thermoplasticity may be used.

The second adhesive filler layer 14 is provided so as to bond the back sheet 16. For the second adhesive filler layer 14, for example, the same material as the adhesive filler 20 may be used. For this reason, detailed description will not be repeated.

The back sheet 16 is provided so as to protect the solar cell module 10 from the back side.

For the back sheet 16, for example, while a sheet having a structure in which an aluminum foil is sandwiched by a resin film, such as PET (polyethylene terephthalate), PEN (polyethylene naphthalate), or PVF (polyvinyl fluoride) is used, and the configuration is not particularly limited.

The back sheet 16 is not limited to a film, and a metal plate, such as a Galvalume steel plate, a stainless steel plate, or a clad steel plate of aluminum and stainless steel, may be used. In addition to these, various plates which are used as the back sheet or a support in a known solar cell module may be used. As the back sheet 16, in particular, a rubber-based sheet, instead of a steel plate, may be used from the viewpoint of reduction in weight, and a plastic sheet similar to the front surface protection layer 26 described below in detail, a plastic resin honeycomb structure, or the like may be used from the viewpoint of a countermeasure against module curvature.

The moisture vapor barrier film 22 is provided so as to protect the solar cell submodule 12 from moisture. The moisture vapor barrier film 22 is not particularly limited, and various known moisture vapor barrier films may be used.

As the moisture vapor barrier film 22, in particular, a moisture vapor barrier film having a moisture vapor transmission rate equal to or lower than 1×10⁻² (g/(m² day)) is preferably used. With the use of such moisture vapor barrier film 22, it is possible to prevent deterioration of the solar cell module 10 due to moisture more reliably over a long period.

As a preferable example of the moisture vapor barrier film 22, a moisture vapor barrier film in which an inorganic compound layer (hereinafter, also referred to as an inorganic layer) having moisture vapor barrier performance or gas barrier performance is formed with various films, such as a PET film and a PEN film, or a plastic film having a thickness of 50 to 100 μm as a substrate may be used.

In regard to the moisture vapor barrier film 22, if necessary transparency can be secured, one or more layers having various functions, such as an adhesion layer, a planarization layer, and an antireflection layer, may be formed on the surface of the moisture vapor barrier film 22.

In the moisture vapor barrier film 22, an inorganic compound having moisture vapor barrier performance is, for example, a diamond-like compound, a metal oxide, a metal nitride, a metal carbide, a metal oxynitride, or a metal oxycarbide. Examples of the inorganic compound include diamond-like carbon (DLC), diamond-like carbon containing silicon, and an oxide, a nitride, a carbide, an oxynitride and an oxycarbide containing at least one selected from Si, Al, In, Sn, Zn, Ti, Cu, Ce, and Ta, and the like.

Of these, an oxide, a nitride, or an oxynitride of a metal selected from Si, Al, In, Sn, Zn, and Ti is preferably used, and in particular, a metal oxide, nitride, or oxynitride of Si or Al is preferably used.

These inorganic layers are formed by, for example, a plasma CVD method, a sputtering method, or the like.

As a preferable example of the moisture vapor barrier film 22, a moisture vapor barrier film in which an organic compound layer (hereinafter, also referred to as an organic layer) serving as an underlayer is provided with various resin films, such as a PET film and a PEN film, as a substrate, and the above-described inorganic layer is formed on the organic layer may be used. With this moisture vapor barrier film 22, it is possible to obtain higher moisture vapor barrier performance.

Examples of an organic compound serving as an underlayer include acrylic resin, methacrylic resin, epoxy resin, polyester, methacrylic acid-maleic acid copolymer, polystyrene, transparent fluororesin, polyimide, fluorinated polyimide, polyamide, polyamideimide, polyetherimide, celluloseacylate, polyurethane, polyetherketone, polycarbonate, fluorine ring modified polycarbonate, alicyclic modified polycarbonate, fluorine ring modified polyester, and the like. Of these, in particular, acrylic resin and methacrylic resin are preferably used.

The organic layer is formed by, for example, an application method using known application means, such as a roll coat method or a spray coat method, a flash deposition method, or the like.

The first adhesive filler layer 24 is provided so as to bond the moisture vapor barrier film 22 and the front surface protection layer 26. For the first adhesive filler layer 24, for example, the same material as the adhesive filler 20 may be used. For this reason, detailed description will not be repeated.

In the first adhesive filler layer 24, thermoplastic olefin-based polymer resin and thermoplastic polyurethane resin are excellent in adhesiveness and thus preferably used.

When the solar cell module 10 is installed outdoors, rain, hail, hailstone, snow, stone, or the like may hit the solar cell module 10. The front surface protection layer 26 protects the solar cell submodule 12 from external force, impact, or like, and a material having high mechanical strength and impact strength, such as wind pressure resistance and hailstorm fall resistance, is used for the front surface protection layer 26.

In addition, the front surface protection layer 26 protects the solar cell module 10 from contamination and suppresses a decrease in the amount of incident light on the solar cell submodule 12 due to contamination or the like.

The front surface protection layer 26 is made of a plastic sheet, and needs to be excellent in transparency, weather resistance, heat resistance, flame resistance, water resistance, moisture resistance, wind pressure resistance, hailstorm fall resistance, chemical resistance, and other characteristics. The front surface protection layer 26 is made of, for example, polycarbonate resin, acrylic resin, methacrylic resin, or a laminate thereof. As regards weather resistance of the front surface protection layer 26, structure deterioration or yellowing due to UV light can be improved by mixing a UV absorbent in resin. Moreover, in order to obtain abrasion resistance, an inorganic coat layer as a hard coat layer may be provided on the surface of the front surface protection layer 26.

The thickness of the front surface protection layer 26 (the thickness of the plastic sheet) is, for example, 0.5 to 2.5 mm, and preferably, 1.0 to 2.0 mm.

When the thickness of the front surface protection layer 26 is smaller than 0.5 mm, it is not possible to sufficiently protect the solar cell submodule 12 from external force, impact, or the like. If the thickness of the front surface protection layer 26 exceeds 2.5 mm, the temperature distribution may increase in an up-down direction during vacuum lamination, and the front surface protection layer 26 may be curved. From the viewpoint of material costs, it is preferable that the thickness is small.

The plastic sheet forming the front surface protection layer 26 is subjected to heat treatment of 100° C. to 140° C., preferably, of 120° C. to 130° C. in advance before vacuum lamination, making it possible to suppress heat shrinkage of the plastic sheet forming the front surface protection layer 26, to relax residual stress of the plastic sheet, and to suppress curvature during vacuum lamination. In this case, the heat treatment time is, for example, 0.5 to 10 hours, and preferably, 1 to 3 hours.

In addition, with the heat treatment, the occurrence of wrinkles or the like in the front surface protection layer 26 due to heat shrinkage during vacuum lamination is suppressed, thereby suppressing a decrease in the amount of incident light on the solar cell submodule 12.

The applicants changed a lamination temperature as shown in Table 1 and examined the influence of the amount of curvature of the plastic sheet (front surface protection layer 26) due to the heat treatment. A sample had a square shape of 20 cm, and the amount of curvature in two orthogonal directions crossing each other with the center of the sample as an origin were examined, and the larger value was set as the amount of curvature.

The amount of curvature was the distance farthest from a surface plate in each direction when the sample after heat treatment was placed on the surface plate.

Experimental Example 1 shown in Table 1 relates to a polycarbonate sheet which has a thickness of 1.0 mm and was not subjected to heat treatment. Experimental Example 2 relates to a polycarbonate sheet which has a thickness of 1.0 mm and was subjected to heat treatment at 130° C. for three hours. Experimental Example 3 relates to a laminated sheet of polycarbonate having a thickness of 1.0 mm and PET, which was subjected to heat treatment at 130° C. for one hour. Experimental Example 4 relates to a polycarbonate sheet which has a thickness of 1.5 mm and was not subjected to heat treatment. Experimental Example 5 relates to a polycarbonate sheet which has a thickness of 1.5 mm and was subjected to heat treatment at 130° C. for three hours. Experimental Example 6 relates to a laminated sheet of polycarbonate having a thickness of 1.5 mm and PET, which was subjected to heat treatment at 130° C. for three hours. Experimental Example 7 relates to a PET sheet which has a thickness of 1.5 mm and was subjected to heat treatment at 130° C. for three hours. Experimental Example 8 relates to a laminated sheet of polycarbonate having a thickness of 1.5 mm and PET, which was subjected to heat treatment at 140° C. for one hour.

As shown in Table 1, in Experimental Examples 1 and 4 in which heat treatment was not performed, the amount of curvature was large regardless of the thickness compared to Experimental Examples 2, 3, and 5 to 8 in which heat treatment was performed. In this way, it is apparent that it is possible to suppress curvature during vacuum lamination with heat treatment.

If the temperature is equal to or higher than 145° C., since the temperature exceeds a glass transition point, it is confirmed that wrinkles occur in the plastic sheet.

TABLE 1

| Lamination | | | | | | | | |
|---|---|---|---|---|---|---|---|---|
| Temperature | Experimental | Experimental | Experimental | Experimental | Experimental | Experimental | Experimental | Experimental |
| (° C.) | Example 1 | Example 2 | Example 3 | Example 4 | Example 5 | Example 6 | Example 7 | Example 8 |
| 130 | 3.3 | 1.6 | — | — | — | — | — | — |
| 135 | 2.9 | 1.3 | — | 1.3 | 1.1 | — | — | — |
| 140 | 1.9 | 0.4 | 0.4 | 1.1 | 0.5 | 0.3 | 0.9 | 0.5 |

Curvature during vacuum lamination may also be suppressed by using the back sheet 16 made of the same plastic sheet as the front surface protection layer 26 to cancel out the curvature of the front surface protection layer 26. Curvature during vacuum lamination may also be suppressed by using an adhesive resin film which is a hot-melt adhesive resin film and has a low melting/bonding temperature such as an urethane-based adhesive resin film as the first adhesive filler layer 24 provided below the plastic sheet forming the front surface protection layer 26.

The applicants examined the relationship between the shrinkage factor and the amount of curvature of the plastic sheet forming the front surface protection layer 26. If the plastic sheet is manufactured by an extrusion method, residual strain occurs in a pullout direction (RD direction). If vacuum lamination is performed, residual strain of the plastic sheet is released, causing curvature. In contrast, if the plastic sheet is subjected to the heat treatment, a thermal shrinkage ratio can be equal to or smaller than 0.04%. In this way, reducing the thermal shrinkage ratio of the plastic sheet, that is, the shrinkage factor makes it possible to suppress curvature of the solar cell module. The amount of curvature d of the plastic sheet is approximated by a Stoney equation shown in Expression 1.

$$d = \frac{{l}^{2}}{2 R} = \frac{{l}^{2}}{2} \frac{6 ( 1 - {v}_{S} ) {t}_{F}}{{E}_{S} {t}_{s}^{2}} σ = \frac{{l}^{2}}{2} \frac{6 ( 1 - {v}_{S} ) {t}_{F}}{{E}_{S} {t}_{s}^{2}} ɛ E ∝ \frac{ɛ}{{t}_{s}^{2}} \qquad [ Equation 1 ]$$

In Expression 1, l is a panel length/2, R is a radius of curvature, Eₛ is Young's modulus of the plastic sheet, vₛ is a Poisson's ratio of the plastic sheet, t_{F} is an undercoat thickness, tₛ is the thickness of the plastic sheet, ε is the shrinkage factor, σ is internal stress, and E is Young's modulus.

As described above, curvature during vacuum lamination may be suppressed by reducing the thermal shrinkage ratio or the shrinkage factor.

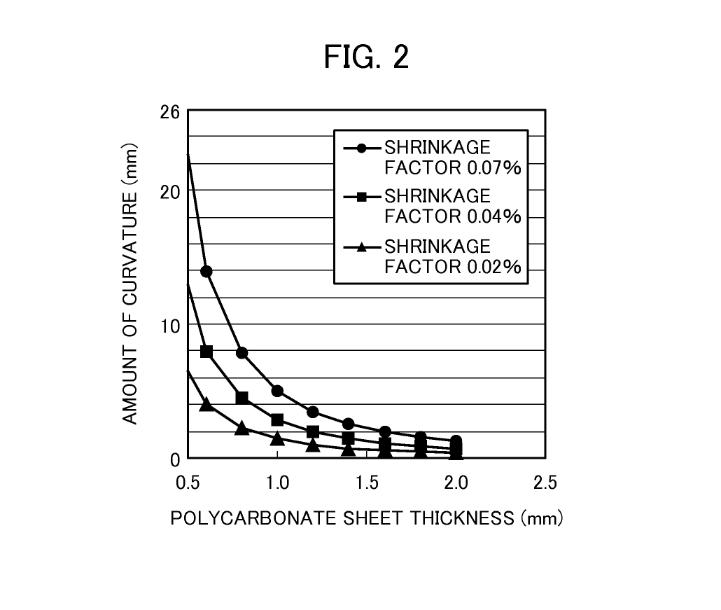

In regard to the polycarbonate sheet, the amount of curvature was calculated for l=10 cm while changing the thickness. The result is shown in FIG. 2. As is apparent from FIG. 2, the amount of curvature of the polycarbonate sheet is suppressed by reducing the shrinkage factor.

In the invention, curvature is suppressed by holding the thermal shrinkage ratio of the plastic sheet forming the front surface protection layer 26 to not greater than 0.04%. If the thermal shrinkage ratio exceeds 0.04%, for example, as the shrinkage factor of 0.07% shown in FIG. 2, the amount of curvature increases, and in particular, when the thickness is small, the amount of curvature rapidly increases. From this, in the invention, the thermal shrinkage ratio of the plastic sheet is held to not greater than 0.04%.

If the plastic sheet is manufactured by an extrusion method, residual strain occurs in a pullout direction (RD direction), and if vacuum lamination is performed, strain is released, causing curvature. In contrast, the thermal shrinkage ratio can be held to not greater than 0.04% by performing heat treatment in advance.

In order to reinforce heat resistance and flame resistance of the solar cell module 10, a fluorine-based transparent resin film, such as ETFE (tetrafluoroethylene), PTFE (polytetrafluoroethylene), PFA (perfluoroalkoxyethylene), PVDF (polyvinyledene fluoride), or FEP (tetrafluoroethylene-hexafluoropropylene copolymer), may be provided on the front surface 26a of the front surface protection layer 26. In this case, the fluorine-based transparent resin film is provided through an adhesive filler layer. The fluorine-based transparent resin film may be provided on the plastic sheet forming the front surface protection layer 26 by a co-extrusion method so as to form an integral sheet. The thickness of the fluorine-based resin film is, for example, 20 to 100 μm.

Next, the solar cell submodule 12 of this embodiment will be described in detail with reference to FIG. 3.

As shown in FIG. 3, the solar cell submodule 12 has a plurality of solar cells 40 bonded in series together on a substrate 50, each solar cell having a lower electrode 32, a light absorbing layer 34, a buffer layer 36, and an upper electrode 38. The solar cell (photoelectric conversion device) 40 uses a semiconductor compound of CIGS as the light absorbing layer 34. The solar cell submodule 12 has a first conductive member 42 and a second conductive member 44.

In the solar cell submodule 12, the substrate 50 is a flexible substrate having a base material 52, an Al (aluminum) layer 54, and an insulating layer 56.

The base material 52 and the Al layer 54 are formed as a single body. The insulating layer 56 is an anodized Al film having a porous structure which is obtained by anodizing the surface of the Al layer 54. A clad substrate in which the base material 52 and the Al layer 54 are laminated and integrated as a single body is referred to as a metal substrate 55.

In the solar cell submodule 12 of the invention, as the (metal) base material 52 forming the substrate 50, mild steel, heat-resistant steel, or stainless steel is used.

The thickness of the base material 52 is not particularly limited, and is preferably 10 to 1000 μm taking into consideration balance between flexibility and strength or rigidity, ease of handling, and the like.

The Al layer 54 is a layer mainly consisting of Al, and Al and various Al alloys may be used. In particular, Al having little impurity but a purity equal to or greater than 99% by mass is preferably used. In terms of purity, for example, Al of 99.99% by mass, Al of 99.96% by mass, Al of 99.9% by mass, Al of 99.85% by mass, Al of 99.7% by mass, Al of 99.5% by mass, or the like is preferably used.

Industrial Al may be used instead of high-purity Al. The use of industrial Al has an advantage from the viewpoint of costs. However, from the viewpoint of insulation of the insulating layer 56, it is important that Si is not precipitated in Al.

The thickness of the Al layer 54 is not particularly limited and may be appropriately selected. In a state where the solar cell submodule 12 is completed, the thickness of the Al layer 54 is preferably equal to or greater 0.1 μm, and equal to or smaller than the thickness of the base material 52.

The Al layer 54 decreases in thickness due to the pretreatment of the Al surface, the formation of the insulating layer 56 by anodization, the generation of an intermetallic compound in the surfaces of the Al layer 54 and the base material 52 at the time of the formation of the light absorbing layer 34, or the like. Accordingly, it is important that the thickness of the Al layer 54 described below at the time of formation is set taking into consideration reduction in thickness due to these factors such that the thickness corresponds to the thickness of the Al layer 54 remaining between the base material 52 and the insulating layer 56 in a state where the solar cell submodule 12 is completed. For this reason, the thickness of the Al layer 54 should be 10 to 50 μm so as to form an insulating layer by anodization.

The insulating layer 56 is formed on the Al layer 54 (the opposite surface to the base material 52). The insulating layer 56 is an anodized Al film which is obtained by anodizing the surface of the Al layer 54.

For the insulating layer 56, various anodized films which are obtained by anodizing Al may be used, and a porous anodized film is preferably used. The anodized film is an alumina oxide coating having pores of several 10 nm, and has high resistance to bending and cracking caused by a heat expansion difference at high temperature, since the Young's modulus of the coating is low.

The thickness of the insulating layer 56 is preferably equal to or greater than 2 μm, and more preferably, equal to or greater than 5 μm. When the insulating layer 56 is too thick, it is not preferable in that flexibility is lowered, and costs and time are required to form the insulating layer 56. Realistically, the thickness of the insulating layer 56 is equal to or smaller than 50 μm, and preferably, equal to or smaller than 30 μm. For this reason, preferably, the thickness of the insulating layer 56 is 2 to 50 μm.

While the solar cell module 10 of this embodiment is of a rigid type, a flexible substrate is used for the solar cell submodule 12, and the insulating layer 56 made of an insulating oxide film having a plurality of pores by anodization is formed on the metal substrate 55 having a thickness of 50 to 200 μm, thereby securing high insulation.

The substrate 50 which is used in the solar cell submodule 12 of this embodiment may be subjected to specific sealing treatment after the Al layer 54 is anodized to form the insulating layer 56. In this manufacturing process, various steps other than indispensable steps may be included. For example, it is preferably that the substrate 50 is completed through a delipidization step of removing stuck rolling oil, a desmutting step of dissolving smut on the surface of the Al layer 54, a surface roughening step of roughening the surface of the Al layer 54, an anodization step of forming an anodized coating on the surface of the Al layer 54, and a sealing step of sealing micropores of the anodized coating.

When each of the base material 52, the Al layer 54, and the insulating layer 56 is provided as a flexible component, the substrate 50 is made flexible as a whole. Accordingly, for example, an alkali supply layer, a lower electrode, a light absorbing layer, an upper electrode, and the like described below can be formed on the insulating layer 56 side of the substrate 50 by a roll-to-roll method.

In the invention, a plurality of layers may be formed successively to form a solar cell structure during single roll unwinding and winding, or a roll unwinding step, a film forming step, and a roll winding step may be performed multiple times to form a solar cell structure. As described below, a scribing step for separating and integrating devices during each film forming step is added to manufacturing by a roll-to-roll method, thereby producing a solar cell submodule having a plurality of solar cells 40 electrically connected in series together.

The invention is not limited to a case where the Al layer 54 and the insulating layer 56 are formed only on one surface of the base material 52, and a structure in which the Al layer 54 and the insulating layer 56 are formed on both surfaces of the base material 52, or a structure in which a single Al layer is provided, that is, an insulating layer made of the above-described anodized film is provided on an Al substrate may also be used as a substrate.

As the metal substrate, a material in which a metal oxide film generated on the surface of the metal substrate by anodization is an insulator may be used. For this reason, in addition to aluminum (Al), specifically, zirconium (Zr), titanium (Ti), magnesium (Mg), copper (Cu), niobium (Nb), tantalum (Ta), or alloys thereof may be used. From the viewpoint of costs and characteristics required for the solar cell module, aluminum is most preferably used.

In order to improve heat resistance, a so-called clad material in which the layer of the above-described metal is formed on a steel plate, such as metal mild steel or stainless steel, by rolling or hot-dip plating may be used.

An alkali supply layer 58 (a supply source of an alkali metal to the light absorbing layer 34) is formed between the insulating layer 56 (substrate 50) and the lower electrode 32, that is, on a front surface 56a of the insulating layer 56.

It is known that, if an alkali metal, in particular, Na is diffused into the light absorbing layer 34 made of CIGS, photoelectric conversion efficiency increases.

The alkali supply layer 58 is a layer which is provided so as to supply an alkali metal to the light absorbing layer 34, and a layer of a compound containing an alkali metal. In the invention, the alkali supply layer 58 is provided between the insulating layer 56 and the lower electrode 32, whereby an alkali metal is diffused into the light absorbing layer 34 through the lower electrode 32 at the time of the formation of the light absorbing layer 34, resulting in improvement in conversion efficiency of the light absorbing layer 34.

The material for the alkali supply layer 58 is not limited, and various materials which as a main component, contains a compound containing an alkali metal (a composition containing an alkali metal compound), such as NaO₂, Na₂S, Na₂Se, NaCl, NaF, or sodium molybdate salt, may be used. In particular, a compound which contains SiO₂ (silicon oxide) as a main component and NaO₂ (sodium oxide) is preferably used.

Since a compound of SiO₂ and NaO₂ is lacking in moisture resistance, and a Na component is liable to be separated and to become carbonate, an oxide containing Ca and having three metal components Si—Na—Ca is preferably used.

In the invention, an alkali metal supply source to the light absorbing layer 34 is not limited to the alkali supply layer 58.

For example, when the insulating layer 56 is the above-described porous anodized film, in addition to the alkali supply layer 58, a compound containing an alkali metal may also be introduced into the pores of the insulating layer 56 to use as an alkali metal supply source to the light absorbing layer 34. Alternatively, the alkali supply layer 58 may not be provided, and a compound containing an alkali metal may only be introduced into the pores of the insulating layer 56 to use as an alkali metal supply source to the light absorbing layer 34.

As an example, when the alkali supply layer 58 is formed by sputtering, only the alkali supply layer 58 can be formed such that there is no compound containing an alkali metal in the insulating layer 56. When the insulating layer 56 is a porous anodized film, and the alkali supply layer 58 is formed by sol-gel reaction or dehydration and drying of a sodium silicate solution, a compound containing an alkali metal is introduced into the pores of the insulating layer 56 as well as the alkali supply layer 58, whereby both the insulating layer 56 and the alkali supply layer 58 can be used as an alkali metal supply source to the light absorbing layer 34.

In the solar cell submodule 12, the lower electrode 32 is formed on the alkali supply layer 58 so as to be arranged at a predetermined gap 33 from an adjacent lower electrode 32. The light absorbing layer 34 is formed on the lower electrodes 32 so as to fill the gap 33 between the lower electrodes 32. The buffer layer 36 is formed on the surface of the light absorbing layer 34.

The light absorbing layer 34 and the buffer layer 36 are arranged on the lower electrodes 32 at a predetermined gap 37. The gap 33 between the lower electrodes 32 and the gap 37 of the light absorbing layer 34 (buffer layer 36) are formed at different positions in the arrangement direction of the solar cells 40.

Moreover, the upper electrode 38 is formed on the surface of the buffer layer 36 so as to fill the gap 37 of the light absorbing layer 34 (buffer layer 36).

The upper electrode 38, the buffer layer 36, and the light absorbing layer 34 are arranged at a predetermined gap 39. The gap 39 is provided at a position different from the gap between the lower electrode 32 and the gap of the light absorbing layer 34 (buffer layer 36).

In the solar cell submodule 12, the solar cells 40 are electrically connected in series together in the longitudinal direction (arrow L direction) of the substrate 50 by the lower electrodes 32 and the upper electrodes 38.

The lower electrode 32 is made of, for example, a Mo electrode. The light absorbing layer 34 is made of a semiconductor compound having a photoelectric conversion function, for example, a CIGS film. The buffer layer 36 is made of, for example, CdS, and the upper electrode 38 is made of, for example, ZnO.

The solar cell 40 is formed to extend in the width direction perpendicular to the longitudinal direction L of the substrate 50. For this reason, the lower electrode 32 and the like also extend in the width direction of the substrate 50.

As shown in FIG. 3, the first conductive member 42 is connected onto the lower electrode 32 of the right-end. The first conductive member 42 is provided so as to extract the output from a negative electrode described below to the outside.

The first conductive member 42 is, for example, an elongated strip-shaped member, extends in a substantially linearly in the width direction of the substrate 50, and is connected to onto the lower electrode 32 of the right-end. As shown in FIG. 3, for example, the first conductive member 42 has a copper ribbon 42a coated with a coating material 42b of an indium-copper alloy. The first conductive member 42 is connected to the lower electrode 32 by, for example, ultrasonic soldering. Alternatively, the first conductive member 42 may be a conductive tape in which In—Sn is hot-dipped to a copper foil and which has an embossing structure, and the conductive tape is attached and connected to the lower electrode 32 by roller pressing.

The second conductive member 44 is formed on the lower electrode 32 of the left-end.

The second conductive member 44 extracts the output from a positive electrode described below to the outside. Similarly to the first conductive member 42, the second conductive member 44 is an elongated strip-shaped member, extends in a substantially linear shape in the width direction of the substrate 50, and is connected to the lower electrode 32 of the left-end.

The second conductive member 44 has the same configuration as the first conductive member 42. For example, the second conductive member 44 is a copper ribbon 44a coated with a coating material 44b of an indium-copper alloy, and similarly to the first conductive member 42, connection may be made by a conductive tape.

The light absorbing layer 34 of the solar cell 40 of this embodiment is made of CIGS, and may be manufactured by a known manufacturing method of CIGS-based solar cell.

In the solar cell submodule 12, if light is incident on the solar cell 40 from the upper electrode 38 side, light passes through the upper electrode 38 and the buffer layer 36, an electromotive force is generated by the light absorbing layer 34, and for example, a current from the upper electrode 38 toward the lower electrode 32 is generated. The arrows shown in FIG. 3 indicate the direction of the current, and an electron movement direction is reverse to the direction of the current. For this reason, in the solar cell submodule 12, the lower electrode 32 of the left-end will be a positive (plus) electrode, and the lower electrode 32 of the right-end will be a negative (minus) electrode, in FIG. 3.

In this embodiment, power generated by the solar cell submodule 12 can be extracted from the first conductive member 42 and the second conductive member 44 to the outside of the solar cell submodule 12.

In this embodiment, the first conductive member 42 is a negative electrode, and the second conductive member 44 is a positive electrode. The first conductive member 42 and the second conductive member 44 may have the polarities reversed, and may be appropriately changed depending on the configuration of the solar cell 40, the configuration of the solar cell submodule 12, and the like.

Although in this embodiment, the solar cells 40 are formed so as to be connected in series together in the longitudinal direction L of the substrate 50 by the lower electrodes 32 and the upper electrodes 38, the invention is not limited thereto. For example, the solar cells 40 may be formed such that the solar cells 40 are connected in series together in the width direction by the lower electrode 32 and the upper electrode 38.

In the solar cell 40, both the lower electrode 32 and the upper electrode 38 are provided so as to extract a current generated by the light absorbing layer 34. Both the lower electrode 32 and the upper electrode 38 are made of a conductive material. The upper electrode 38 on the light incident side needs to have a translucency.

The lower electrode (back surface electrode) 32 is made of, for example, Mo, Cr, W, or a combination thereof. The lower electrode 32 may have a single layer structure or may have a laminated structure, such as a two-layered structure. The lower electrode 32 is preferably made of Mo.

The thickness of the lower electrode 32 is preferably equal to or greater than 100 nm, and more preferably, 0.45 to 1.0 μm.

The method of forming the lower electrode 32 is not particularly limited, and the lower electrode 32 may be formed by a vapor-phase film formation method such as an electron-beam evaporation method, a sputtering method, or the like.

The upper electrode (transparent electrode) 38 is made of, for example, ZnO, in which Al, B, Ga, In, Sb, or the like is added, indium-tin oxide (ITO) or SnO₂, or a combination thereof. The upper electrode 38 may have a single layer structure or may have a laminated structure, such as a two-layered structure. The thickness of the upper electrode 38 is not particularly limited, and is preferably 0.3 to 1 μm.

The method of forming the upper electrode 38 is not particularly limited, and the upper electrode 38 may be formed by a vapor-phase film formation method, such as an electron-beam evaporation method, a sputtering method, or the like, or an application method.

The buffer layer 36 is formed so as to protect the light absorbing layer 34 at the time of the formation of the upper electrode 38 and to transmit light incident on the upper electrode 38 to the light absorbing layer 34.

The buffer layer 36 is made of, for example, CdS, ZnS, ZnO, ZnMgO, ZnS(O,OH), or a combination thereof.

The thickness of the buffer layer 36 is preferably 0.03 to 0.1 μm. The buffer layer 36 is formed by, for example, a CBD (Chemical Bath Deposition) method.

The light absorbing layer 34 is a layer which absorbs light having passed through the upper electrode 38 and the buffer layer 36 to generate a current, and has a photoelectric conversion function. The light absorbing layer 34 is made of a CIGS film, and the CIGS film is made of a semiconductor having a chalcopyrite crystal structure. The composition of the CIGS film is, for example, Cu (In₁₋ₓGaₓ) Se₂ (CIGS).

As the method of forming the CIGS film, 1) a multi-source evaporation method, 2) a selenization method, 3) a sputtering method, 4) a hybrid sputtering method, 5) a mechanochemical processing method, and the like are known.

Other CIGS forming methods include a screen printing method, a close-spaced sublimation method, a MOCVD method, and a spray method (wet film formation method). A crystal having a desired composition can be obtained by, for example, forming a particulate film containing a Ib group element, a IIIb group element, and a VIb group element on a substrate by a screen printing method (wet film formation method) or a spray method (wet film formation method), or the like, and performing thermal decomposition treatment (at this time, thermal decomposition treatment may be performed under an atmosphere of a VIb group element) (JP 9-74065 A, JP 9-74213 A, and the like).

According to this film formation method, if the temperature is equal to or higher than 500° C. when forming CIGS on the substrate, satisfactory photoelectric conversion efficiency is exhibited. However, taking into consideration manufacturing by a roll-to-roll method, a multi-source evaporation method having a short process time is preferably used. In particular, a bylayer method is preferably used.

As described above, the solar cell submodule 12 of the invention is manufactured by bonding the solar cells 40 in series on the substrate 50, the manufacturing method thereof may be the same as those of various known solar cell.

Hereinafter, an example of a method of manufacturing the solar cell submodule 12 shown in FIG. 3 will be described.

First, the substrate 50 which is formed in the above-described manner is prepared. Then, the alkali supply layer 58 is formed on the surface of the insulating layer 56 of the substrate 50 by, for example, sputtering using soda-lime-silica glass as a target or a sol-gel method using alkoxide containing Si and Na.

Subsequently, a Mo film which will be the lower electrode 32 is formed on the surface of the alkali supply layer 58 by, for example, a sputtering method using a film formation device.

Subsequently, the gap 33 which extends in the width direction of the substrate 50 is formed by, for example, scribing a predetermined position of the Mo film using a laser scribing method. Thereby, the lower electrodes 32 which are separated from each other by the gap 33 are formed.

Subsequently, a CIGS film is formed as the light absorbing layer 34 (p-type semiconductor layer) so as to cover the lower electrode 32 and to fill the gap 33. The CIGS film is formed by any film formation method described above.

Subsequently, a CdS layer (n-type semiconductor layer) which will be the buffer layer 36 is formed on the light absorbing layer 34 (CIGS film) by, for example, a CBD method. Thereby, a pn-junction semiconductor layer is formed.

Subsequently, the gap 37 which extends in the width direction of the substrate 50 and reaches the lower electrode 32 is formed at a predetermined position different from the gap 33 in the arrangement direction of the solar cells 40 by, for example, scribing the predetermined position using a laser scribing method.

Subsequently, for example, an ITO layer, a ZnO layer with Al, B, Ga, Sb, or the like which will be the upper electrode 38 is formed on the buffer layer 36 by a sputtering method or an application method so as to fill the gap 37.

Subsequently, the gap 39 which extends in the width direction of the substrate 50 and reaches the lower electrode 32 is formed at a predetermined position different from the gaps 33 and 37 in the arrangement direction of the solar cells 40 by, for example, scribing the predetermined position using a laser scribing method. Thereby, the solar cells 40 are formed.

Subsequently, the solar cells 40 formed on the lower electrodes 32 of the left and right-end in the longitudinal direction L of the substrate 50 are removed by, for example, laser scribing or mechanical scribing to expose the lower electrodes 32. Then, the first conductive member 42 is connected onto the lower electrode 32 of the right-end and the second conductive member 44 is connected onto the lower electrode 32 of the left-end using, for example, ultrasonic soldering.

Thereby, as shown in FIG. 3, it is possible to manufacture the solar cell submodule 12 in which a plurality of solar cells 40 are electrically connected in series together.

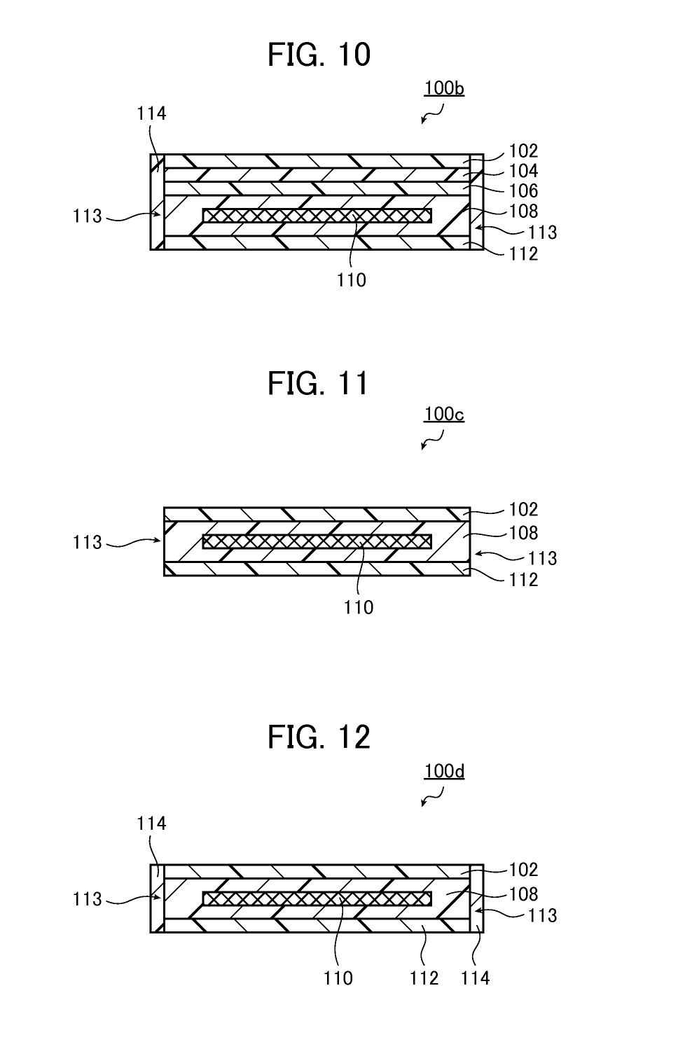

FIGS. 9 and 10 are schematic sectional views of a solar cell module of the related art. A first solar cell module 100a of the related art shown in FIG. 9 has a moisture vapor barrier film 106 below a front surface protection layer 102 through an adhesive 104, and a solar cell submodule 110 which is surrounded by an adhesive filler layer 108 is provided between the moisture vapor barrier film 106 and a back surface protection layer 112. A second solar cell module 100b of the related art shown in FIG. 10 is different from the solar cell module 100a shown in FIG. 9 in that seal materials 114 are provided on lateral end surfaces 113, and other parts are the same as those of the solar cell module 100a.

In general, a transparent conductive film, such as an ITO film, a ZnO(Al) film, or a ZnO(B) film, is formed on the surface of the solar cell submodule. The transparent conductive film is very vulnerable to moisture by nature. In the case of the solar cell module 100a having the configuration shown in FIG. 9, since the lateral end surfaces 113 of the adhesive filler layer 108 surrounding the solar cell submodule 110 are exposed to the outside, moisture infiltrates through the lateral end surfaces 113 and reaches the surface of the solar cell submodule 110, causing an increase in resistance of the transparent conductive film, or reaches a junction below the transparent conductive film, causing a leak current. For this reason, there is a problem in that the characteristics of the solar cell module are deteriorated.

Meanwhile, in the case of the solar cell module 100b having the configuration shown in FIG. 10, since the lateral end surfaces 113 of the adhesive filler layer 108 are covered with the seal materials 114, it apparently appears that it is possible to block moisture infiltration from the lateral end surfaces 113. However, the outer circumference of the solar cell module 100b is bent due to the difference in heat expansion and heat shrinkage of the front surface protection layer 102, the moisture vapor barrier film 106, the back surface protection layer 112, the adhesive 104, the adhesive filler layer 108, or the like under a high-temperature and high-humidity environment, the edge portion of the seal material 114 is separated or a cavity is partially generated, and moisture infiltrates into the inside therethrough. As a result, it is not possible to block moisture infiltration from the lateral end surfaces 113 of the solar cell module 100b.

In contrast, in the solar cell module 10 shown in FIG. 1A, since the intermediate seal material 18 is arranged inside the edge of the back sheet 16, and the intermediate seal material 18 is located inside the solar cell module 10 in which the moisture vapor barrier film 22 and the back sheet 16 are bonded together, the intermediate seal material 18 is not exposed to the outside, and there is no problem that the intermediate seal material 18 is bent or separated due to the difference in heat expansion and heat shrinkage. The intermediate seal material 18 is at least provided from the back surface 12b of the solar cell submodule 12 to the moisture vapor barrier film 22, and the intermediate seal material 18 comes into contact with the moisture vapor barrier film 22 and seals the adhesive filler 20, whereby it becomes possible to block moisture infiltration from the lateral surfaces of the adhesive filler 20 and to suppress moisture infiltration from at least the front surface 12a side of the solar cell submodule 12, that is, from the upper side. In addition, it is also possible to reduce a corrosion product, such as acetate, which is generated by reaction between moisture and the adhesive constituting the adhesive filler 20, thereby completing the solar cell module 10 which can exhibit stable performance over a long period.

Although in the solar cell module 10 shown in FIG. 1A, the intermediate seal material 18 is provided from the back surface 12b of the solar cell submodule 12 to the moisture vapor barrier film 22, the intermediate seal material 18 may be brought into contact also with the back sheet 16 so as to separate the second adhesive filler layer 14. With this configuration, it becomes possible to suppress moisture infiltration from the second adhesive filler layer 14 by the intermediate seal material 18, to more effectively reduce a corrosion product which is generated by reaction between moisture and the second adhesive filler layer 14, and to suppress degradation in conversion efficiency of the solar cell submodule 12 caused by increase in resistance due to change in quality of the transparent electrode of the solar cell submodule 12, thereby completing the solar cell module 10 which can exhibit stable performance over a long period.

In this embodiment, by using the plastic sheet for the front surface protection layer 26, it is possible to obtain mechanical strength and impact strength, such as wind pressure resistance and hailstorm fall resistance, equal to or more than tempered super white glass. In addition, if the thickness is equal, the mass can be reduced to not greater than 50% because the plastic sheet has a density of 1.1 to 1.2 g/cm³ as compared with 2.5 g/cm³, the density of glass. In general, the thickness of the tempered super white glass is 3 mm but by reducing the thickness of the front surface protection layer 26 to as small as 1 to 2 mm, the mass per unit area can be reduced to 1.2 to 2.4 kg/m². Therefore, it is possible to achieve reduction of the weight up to 16 to 32% compared to a case where the tempered super white glass is used.

With the heat treatment, the occurrence of wrinkles due to heat shrinkage during vacuum lamination is suppressed, thereby also suppressing a decrease in the amount of incident light on the solar cell submodule 12.

Next, a second embodiment will be described.

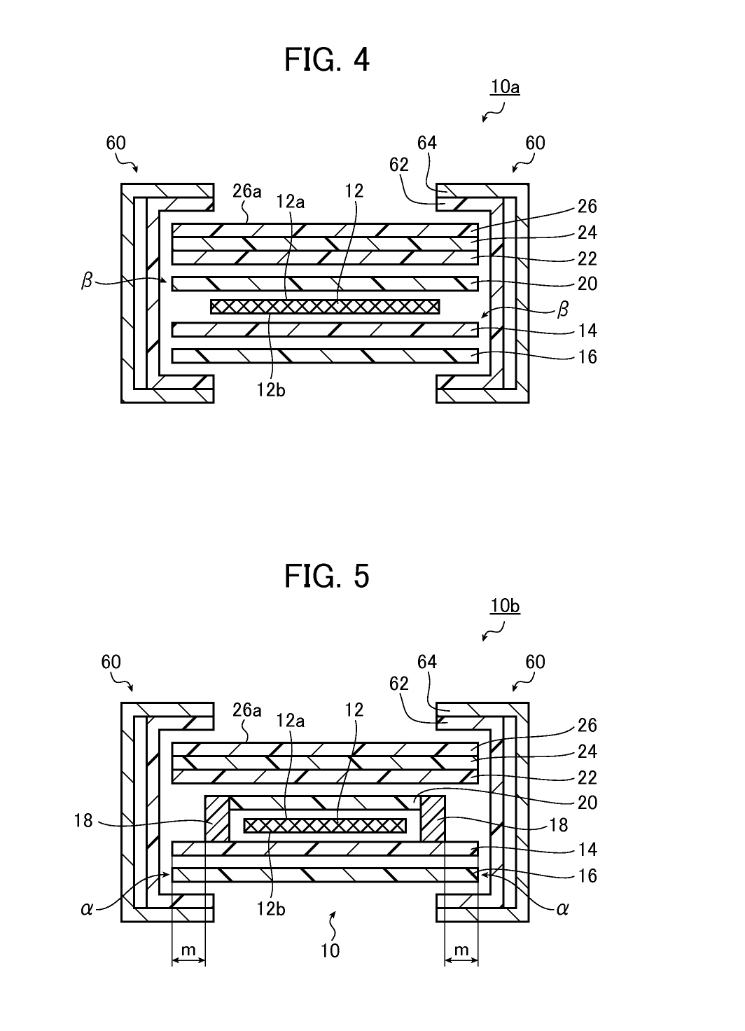

FIG. 4 is a schematic sectional view showing the arrangement state of respective members before vacuum lamination of a solar cell module according to a second embodiment of the invention.

In this embodiment, the same constituent parts as those in the solar cell module 10 shown in FIGS. 1A and 1B are represented by the same reference numerals, and detailed description thereof will not be repeated.

As shown in FIG. 4, a solar cell module 10a of this embodiment is different from the solar cell module 10 (see FIGS. 1A and 1B) of the first embodiment in that no intermediate seal material 18 is provided, and frame members 60 are provided in edge portions β of the second adhesive filler layer 14, the back sheet 16, the moisture vapor barrier film 22, the first adhesive filler layer 24, and the front surface protection layer 26, and other parts are the same as those of the solar cell module 10 of the first embodiment, thus detailed description thereof will not be repeated.

In the solar cell module 10a of this embodiment, the frame member 60 is provided so as to improve mechanical resistance of the solar cell module 10a and to improve moisture diffusion resistance and moisture resistance of the edge portion β. The frame member 60 has an outer edge seal material 62 and an outer frame material 64. The outer edge seal material 62 is provided inside, and the outer frame material 64 is provided outside.

For the outer edge seal material 62, for example, butyl rubber, polyisoprene, or isoprene having thermoplasticity is used.

The outer frame material 64 may have a foil shape or a frame shape. The outer frame material 64 may be formed of, for example, aluminum, an aluminum alloy, copper, or a copper alloy. For example, when a metal foil is used as the outer frame material 64, aluminum, an aluminum alloy, copper, or a copper alloy may be used. The thickness of the metal foil is, for example, 50 to 300 μm. The metal foil may have an adhesive material provided in advance.

For the outer frame material 64, a metal foil tape in which a black PET film is bonded to a metal foil may be used from the viewpoint of aesthetics and design of the solar cell module 10a.

When moisture resistance is required, for example, butyl rubber is used for the outer edge seal material 62, and an L-shaped aluminum frame is used for the outer frame material 64.

In the solar cell module 10a of this embodiment, as in the first embodiment, the fluorine-based transparent resin film may be formed on the front surface 26a of the front surface protection layer 26.

The solar cell module 10a of this embodiment may be produced as follows. First, as in the first embodiment, the second adhesive filler layer 14 and the back sheet 16 are laminated and arranged on the back surface 12b of the solar cell submodule 12. Next, as in the first embodiment, the adhesive filler 20, the moisture vapor barrier film 22, the first adhesive filler layer 24, and the front surface protection layer 26 are laminated and arranged on the front surface 12a of the solar cell submodule 12. Accordingly, the respective members are laminated and arranged as shown in FIG. 4. Thereafter, as in the first embodiment, in a state where the respective members are laminated and arranged, vacuum lamination is performed under the conditions of, for example, temperature of 130 to 140° C. and vacuum/press/retention of 15 to 30 minutes in total.

Thereafter, the outer edge seal material 62 of the frame member 60 is provided so as to cover the edge portion β, a part of the surface of the front surface protection layer 26, and a part of the surface of the back sheet 16. Thereafter, the outer frame material 64 is bonded onto the outer edge seal material 62. Thereby, the solar cell module 10a of this embodiment is formed.

In this embodiment, as in the first embodiment, when producing the solar cell module 10a, the above-mentioned fluorine-based transparent resin film may be laminated and arranged on the front surface 26a of the front surface protection layer 26, and vacuum lamination may be performed in this state, thereby producing the solar cell module.

In the solar cell module 10a of this embodiment, it is possible to obtain the same effects as the solar cell module 10 of the first embodiment.

Next, a third embodiment will be described.

FIG. 5 is a schematic sectional view showing the arrangement state of respective members before vacuum lamination of a solar cell module according to a third embodiment of the invention.

In this embodiment, the same constituent parts as those in the solar cell module 10 shown in FIGS. 1A and 1B are represented by the same reference numerals, and detailed description thereof will not be repeated.

As shown in FIG. 5, a solar cell module 10b of this embodiment is different from the solar cell module 10 of the first embodiment (see FIGS. 1A and 1B) in that frame members 60 are provided in the edge portions α of the solar cell module 10, and other parts are the same as those of the solar cell module 10 of the first embodiment, thus detailed description thereof will not be repeated.

In the solar cell module 10b of this embodiment, the frame member 60 is provided so as to improve mechanical resistance and to improve moisture diffusion resistance and moisture resistance of the edge portion α.

The frame member 60 has the same configuration as the solar cell module 10a of the second embodiment, thus detailed description thereof will not be repeated.

In the solar cell module 10b of this embodiment, as in the first embodiment, the above-mentioned fluorine-based transparent resin film may be formed on the front surface 26a of the front surface protection layer 26.

The solar cell module 10b of this embodiment may be produced as follows. First, as in the first embodiment, as shown in FIG. 1B, the second adhesive filler layer 14 and the back sheet 16 are arranged on the back surface 12b of the solar cell submodule 12, and the adhesive filler 20, the moisture vapor barrier film 22, the first adhesive filler layer 24, and the front surface protection layer 26 are arranged on the front surface 12a of the solar cell submodule 12. Accordingly, the respective members are laminated as shown in FIG. 5. Thereafter, as in the first embodiment, for example, vacuum lamination is performed under the conditions of, for example, a temperature of 130 to 140° C. and vacuum/press/retention of 15 to 30 minutes in total.

Thereafter, the outer edge seal material 62 of the frame member 60 is provided so as to cover the edge portion α, a part of the surface of the front surface protection layer 26, and a part of the surface of the back sheet 16. Thereafter, the outer frame material 64 is bonded onto the outer edge seal material 62. Thereby, the solar cell module 10b of this embodiment is formed.

In this embodiment, as in the first embodiment, when producing the solar cell module 10b, the above-mentioned fluorine-based transparent resin film may be laminated and arranged on the front surface 26a of the front surface protection layer 26, and vacuum lamination may be performed in this state, thereby producing the solar cell module.

In the solar cell module 10b of this embodiment, it is possible to obtain the same effects as the solar cell module 10 of the first embodiment and to improve mechanical resistance, moisture diffusion resistance, and moisture resistance.

Next, a fourth embodiment will be described.

This embodiment relates to a method of manufacturing a solar cell module.

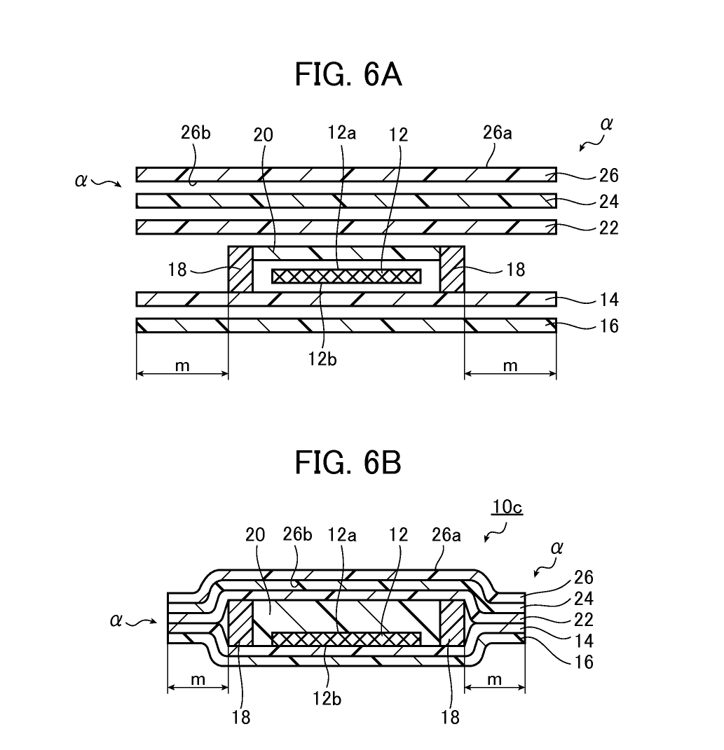

FIG. 6A is a schematic sectional view showing the arrangement state of respective members before vacuum lamination of a solar cell module according to a fourth embodiment of the invention, and FIG. 6B is a schematic sectional view showing the solar cell module according to the fourth embodiment of the invention.

In this embodiment, the same constituent parts as those in the solar cell module 10 shown in FIGS. 1A and 1B are represented by the same reference numerals, and detailed description thereof will not be repeated.

A method of manufacturing a solar cell module 10c of this embodiment is different from the method of manufacturing the solar cell module 10 of the first embodiment in that the front surface protection layer 26 (plastic sheet) is subjected to heat treatment in advance, and thereafter, in order to improve adhesiveness between the plastic sheet constituting the front surface protection layer 26 and the first adhesive filler layer 24, corona discharge treatment is performed on the back surface 26b of the front surface protection layer 26 (the back surface of the plastic sheet) to be bonded to the first adhesive filler layer 24, and other parts of the method of manufacturing the solar cell module 10c are the same as the method of manufacturing the solar cell module 10 of the first embodiment.

In this embodiment, after the corona treatment, a silane coupling agent, an aluminate coupling agent, or a titanate coupling agent is applied as a primer to the back surface 26b of the front surface protection layer 26, and dried at room temperature for 0.5 to 2 hours. Thereafter, the front surface protection layer 26 is arranged such that the surface applied with a primer faces the first adhesive filler layer 24. When the plastic sheet constituting the front surface protection layer 26 is polycarbonate, a titanate coupling agent is preferably used as a primer.

As described below, the plastic sheet constituting the front surface protection layer 26 is arranged such that the surface subjected to the corona treatment and applied with a primer, that is, the back surface 26b faces the first adhesive filler layer 24.

The thickness of the front surface protection layer 26 (the thickness of the plastic sheet) is, for example, 0.5 to 2.0 mm, and preferably, 1.0 to 1.5 mm.

When the thickness of the front surface protection layer 26 is smaller than 0.5 mm, it is not possible to protect sufficiently the solar cell submodule 12 from external force, impact, or the like. On the other hand, if the thickness of the front surface protection layer 26 exceeds 2.0 mm, the temperature distribution may increase in the up-down direction during vacuum lamination, and the front surface protection layer 26 may be curved. From the viewpoint of material costs, it is preferable that the thickness is small.

In the plastic sheet constituting the front surface protection layer 26, at least the back surface 26b which is bonded to the first adhesive filler layer 24 may have an embossing structure. The height of unevenness of the embossing structure is, for example, 10 to 1000 μm.

In this way, with the embossing structure, it is possible to improve adhesiveness to the first adhesive filler layer 24 by an anchor effect. The embossing structure is formed by, for example, heating the plastic sheet to be equal to or higher than the glass transition point.

When the plastic sheet constituting the front surface protection layer 26 is made of polycarbonate, for example, unevenness of glass fiber cloth which is used during vacuum lamination is used as a mold of embossing, and pressing is performed using a vacuum laminator at 140 to 160° C. for 15 to 30 minutes, thereby easily producing the embossing structure. Of course, when producing the embossing structure, other hot pressing methods using a mold may be used.

In addition, for the back sheet 16, if the same plastic sheet as the front surface protection layer 26 is used to cancel curvature by the front surface protection layer 26, curvature during vacuum lamination can be suppressed. Moreover, even if an adhesive resin film which is a hot-melt adhesive resin film and has a low melting and bonding temperature, such as, for example, an urethane-based adhesive resin film, is used as the first adhesive filler layer 24 which is provided below the plastic sheet constituting the front surface protection layer 26, it is possible to suppress curvature during vacuum lamination.

The solar cell module 10c of this embodiment may be produced as follows.

First, as shown in FIG. 6A, the second adhesive filler layer 14 and the back sheet 16 are laminated and arranged on the back surface 12b of the solar cell submodule 12. Next, the adhesive filler 20, the intermediate seal material 18, and the moisture vapor barrier film 22 are arranged on the front surface 12a of the solar cell submodule 12. The intermediate seal material 18 is arranged in the periphery of the adhesive filler 20 at a distance m, say 5 to 30 mm, inwardly from the edge portion α, and the moisture vapor barrier film 22 is laminated and arranged so as to cover the adhesive filler 20 and the intermediate seal material 18.

The first adhesive filler layer 24 is arranged on the moisture vapor barrier film 22, and the front surface protection layer 26 is arranged on the first adhesive filler layer 24. Accordingly, the respective members are laminated and arranged as shown in FIG. 6A.

The front surface protection layer 26 is subjected to heat treatment in advance, for example, under the above-described conditions or the like, and corona treatment and primer application are performed on the front surface 26b which is bonded to the first adhesive filler layer 24.

Thereafter, in a state where the respective members are laminated and arranged, for example, vacuum lamination is performed using a vacuum laminator having lifting means, an impingement plate, and heating means under the conditions of, for example, a temperature of 125 to 140° C. and vacuum/press/retention of 15 to 30 minutes in total. Thereby, the solar cell module 10c of this embodiment shown in FIG. 6B is produced.

The solar cell submodule 12 of the solar cell module 10c of this embodiment has the same configuration as shown in FIG. 3, thus detailed description thereof will not be repeated.

In the solar cell module 10c of this embodiment shown in FIG. 6B, the mechanical strength and impact strength, such as wind pressure resistance and hailstorm fall resistance, can be equal to or more than the white-plate reinforced glass. If the thickness is identical, the plastic sheet can have density of 1.1 to 1.2 g/cm³ compared with 2.5 g/cm³, the density of glass and thus the mass can be equal to or smaller than 50%.

In general, while the thickness of the tempered super white glass is 3.2 mm, the mass per unit area can be reduced to 1.2 to 2.4 kg/m² by reducing the thickness of the front surface protection layer to as thin as 1 to 2 mm. In this case, it becomes possible to achieve reduction of the weight up to 16 to 32% of that of the tempered super white glass.

As in the solar cell module 10c, when a plastic sheet is used for the front surface protection layer, the coefficient of linear expansion is large, and adhesiveness between the plastic sheet and the adhesive filler layer is very bad. For this reason, there is a major problem in that the solar cell module is curved with a temperature rise, separation occurs between the constituent layers of the solar cell, or the like. Accordingly, appropriate selection of constituent materials and improvement of adhesiveness are required. According to the solar cell module of this embodiment, as a countermeasure against these, heat treatment is performed in advance on the polycarbonate sheet which will be the front surface protection layer, corona treatment and application and drying of a primer made of a titanate coupling agent are then performed, and thermoplastic olefin-based polymer resin or thermoplastic polyurethane resin is used for the first adhesive filler layer 24, whereby it is possible to manufacture a solar cell module while improving adhesiveness and suppressing curvature, separation, and the like.

In this embodiment, as in the first embodiment, it is possible to more reliably suppress defects, such as performance deterioration and electric wire corrosion, due to moisture or vapor moisture. Even if moisture enters, it is possible to prevent moisture from reaching the transparent electrode of the solar cell or the like.

In particular, the moisture vapor barrier film 22 is arranged such that the surface on which an inorganic layer and an organic layer are formed faces the solar cell submodule, thereby preventing moisture diffusion through the base material.

In this way, according to the invention, it is possible to realize a solar cell module which is capable of preventing infiltration of moisture into the solar cell module, and exhibiting stable performance and being stably used over a long period.

A substrate in which an anodized aluminum film is formed on the surface of a metal sheet which may be manufactured by a roll-to-roll manufacturing method is used as the solar cell submodule 12 instead of a glass substrate, and a CIGS film is formed as the light absorbing layer, whereby a solar cell module which is lightweight and low-cost is obtained.

According to the method of manufacturing the solar cell module 10c of this embodiment, it is possible to suitably manufacture the solar cell module 10c having excellent characteristics described above.

FIGS. 11 and 12 are schematic sectional views of a solar cell module of the related art. A third solar cell module 100c shown in FIG. 11 has a solar cell submodule 110 which is surrounded by an adhesive filler layer 108, and a front surface protection layer 102 is provided on the top surface of the adhesive filler layer 108. A back surface protection layer 112 is provided on the bottom surface of the adhesive filler layer 108.

A fourth solar cell module 100d of the related art shown in FIG. 12 is different from the solar cell module 100c shown in FIG. 11 in that seal materials 114 are provided on lateral end surfaces 113, and other parts are the same as those of the solar cell module 100c.

In general, the surface of the solar cell submodule is formed of a transparent conductive film, such as an ITO film, a ZnO(Al) film, or a ZnO(B) film. The transparent conductive film is very vulnerable to moisture by nature. In the case of the solar cell module 100c having the configuration shown in FIG. 11, the lateral end surfaces 113 of the adhesive filler layer 108 surrounding the solar cell submodule 110 are exposed to the outside, moisture infiltrates through the lateral end surfaces 113 and reaches the surface of the solar cell submodule 110, causing an increase in resistance of the transparent conductive film, or reaches a junction portion below the transparent conductive film, causing a leak current. For this reason, there is a problem in that the characteristics of the solar cell module are deteriorated.

Meanwhile, in the case of the solar cell module 100d having the configuration shown in FIG. 12, since the lateral end surfaces 113 of the adhesive filler layer 108 are covered with the seal materials 114, it apparently appears that it is possible to block moisture infiltration from the lateral end surfaces 113. However, the outer circumference of the solar cell module 100d is bent due to the difference in heat expansion and heat shrinkage of adhesive filler layer 108, the front surface protection layer 102, the back surface protection layer 112, or the like under a high-temperature and high-humidity environment, the edge portion of the seal material 114 is separated or a cavity is partially generated, and moisture infiltrates into the inside therethrough. As a result, it is not possible to block moisture infiltration from the lateral end surfaces 113 of the solar cell module 100d.

In contrast, in the solar cell module 10c shown in FIG. 6B, since the intermediate seal material 18 is arranged inside the edge of the back sheet 16, and the intermediate seal material 18 is located inside the solar cell module 10 in which the moisture vapor barrier film 22 and the back sheet 16 are bonded together, the intermediate seal material 18 is not exposed to the outside, and there is no problem that the intermediate seal material 18 is bent or separated due to the difference in heat expansion and heat shrinkage. The intermediate seal material 18 is at least provided from the back surface 12b of the solar cell submodule 12 to the moisture vapor barrier film 22, and the intermediate seal material 18 comes into contact with the moisture vapor barrier film 22 to seal the adhesive filler 20, whereby it becomes possible to block moisture infiltration from the lateral surface of the adhesive filler 20 and to suppress moisture infiltration from the front surface 12a of the solar cell submodule 12, that is, from the upper side. In addition, it is also possible to reduce a corrosion product, for example, acetate which is generated by reaction between moisture and the adhesive constituting the adhesive filler 20, thereby completing the solar cell module 10 which can exhibit stable performance over a long period.

Although in the solar cell module 10c shown in FIG. 6B, the intermediate seal material 18 is provided from the back surface 12b of the solar cell submodule 12 to the moisture vapor barrier film 22, the intermediate seal material 18 may be brought into contact with the back sheet 16 so as to separate the second adhesive filler layer 14. With this configuration, it becomes possible to suppress moisture infiltration from the second adhesive filler layer 14 by the intermediate seal material 18, to more effectively reduce a corrosion product which is generated by reaction between moisture and the second adhesive filler layer 14, and to suppress degradation in conversion efficiency of the solar cell submodule 12 caused by increase in resistance due to change in quality of the transparent electrode of the solar cell submodule 12, thereby completing the solar cell module 10c which can exhibit stable performance over a long period.

Next, a fifth embodiment will be described.

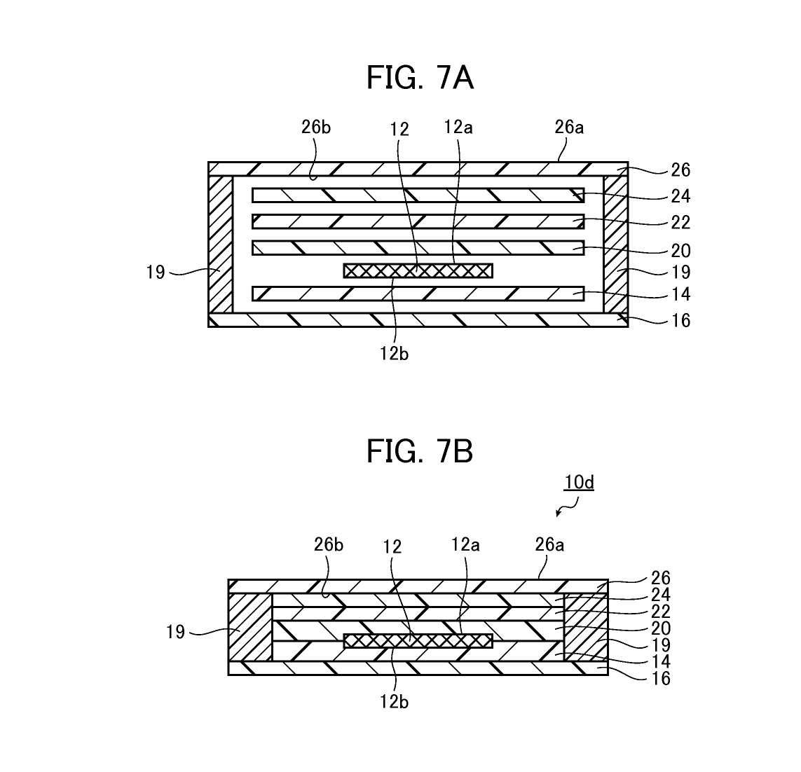

FIG. 7A is a schematic sectional view showing the arrangement state of respective members before vacuum lamination of a solar cell module according to a fifth embodiment of the invention, and FIG. 7B is a schematic sectional view showing the solar cell module according to the fifth embodiment of the invention.

In this embodiment, the same constituent parts as those in the solar cell module 10c of the fourth embodiment shown in FIGS. 6A and 6B are represented by the same reference numerals, and detailed description thereof will not be repeated.

A solar cell module 10d of this embodiment shown in FIG. 7B is different from the solar cell module 10c of the fourth embodiment (see FIG. 6B) in that the solar cell submodule 12 is sealed by the adhesive filler 20 and the second adhesive filler layer 14, no intermediate seal material 18 is provided, and surrounding edge seal material 19 is provided between the back sheet 16 and the front surface protection layer 26, and other parts are the same as those of the solar cell module 10c of the fourth embodiment, thus detailed description thereof will not be repeated.

In the solar cell module 10d of this embodiment shown in FIG. 7B, similarly to the intermediate seal material 18 of the fourth embodiment, the edge seal material 19 raises mechanical resistance of the solar cell module 10d and raises moisture diffusion resistance and moisture resistance of the edge of the solar cell module 10d. For the edge seal material 19, the same material as the intermediate seal material 18 may be used, and for example, butyl rubber, polyisoprene, isoprene, or polyolefin having thermoplasticity is used.

The solar cell module 10d of this embodiment may be manufactured as follows.

First, as shown in FIG. 7A, the second adhesive filler layer 14 and the back sheet 16 are laminated and arranged on the back surface 12b of the solar cell submodule 12. Then, as in the fourth embodiment, the adhesive filler 20, the moisture vapor barrier film 22, the first adhesive filler layer 24, and the front surface protection layer 26 are arranged on the front surface 12a of the solar cell submodule 12.

Further, the edge seal material 19 are arranged between the back sheet 16 and the front surface protection layer 26 so as to surround the periphery of the second adhesive filler layer 14, the back sheet 16, the adhesive filler 20, the moisture vapor barrier film 22, and the first adhesive filler layer 24. Accordingly, the respective members are laminated and arranged as shown in FIG. 7A.

Thereafter, in a state where the respective members are laminated and arranged, for example, vacuum lamination is performed using a vacuum laminator having lifting means, an impingement plate, and heating means under the conditions of, for example, a temperature of 120 to 145° C. and vacuum/press/retention of 15 to 30 minutes in total. Thereby, the solar cell module 10d of this embodiment shown in FIG. 7B is produced.

When producing the solar cell module 10d, the edge seal material 19 may be stuck to the back surface 26b of the front surface protection layer 26, and after the respective members of the solar cell module 10d are laminated, temporal fixing of the edge seal material 19 may be performed and then, vacuum lamination may be performed.

In this embodiment, as in the fourth embodiment, when producing the solar cell module 10d, the above-described fluorine-based transparent resin film may be laminated and arranged on the front surface 26a of the front surface protection layer 26, and vacuum lamination may be performed in this state, thereby producing a solar cell module.

In the solar cell module 10d of this embodiment, the edge seal material 19 is provided, whereby it is possible to obtain the same effects as the solar cell module 10c of the fourth embodiment.

Next, a sixth embodiment will be described.

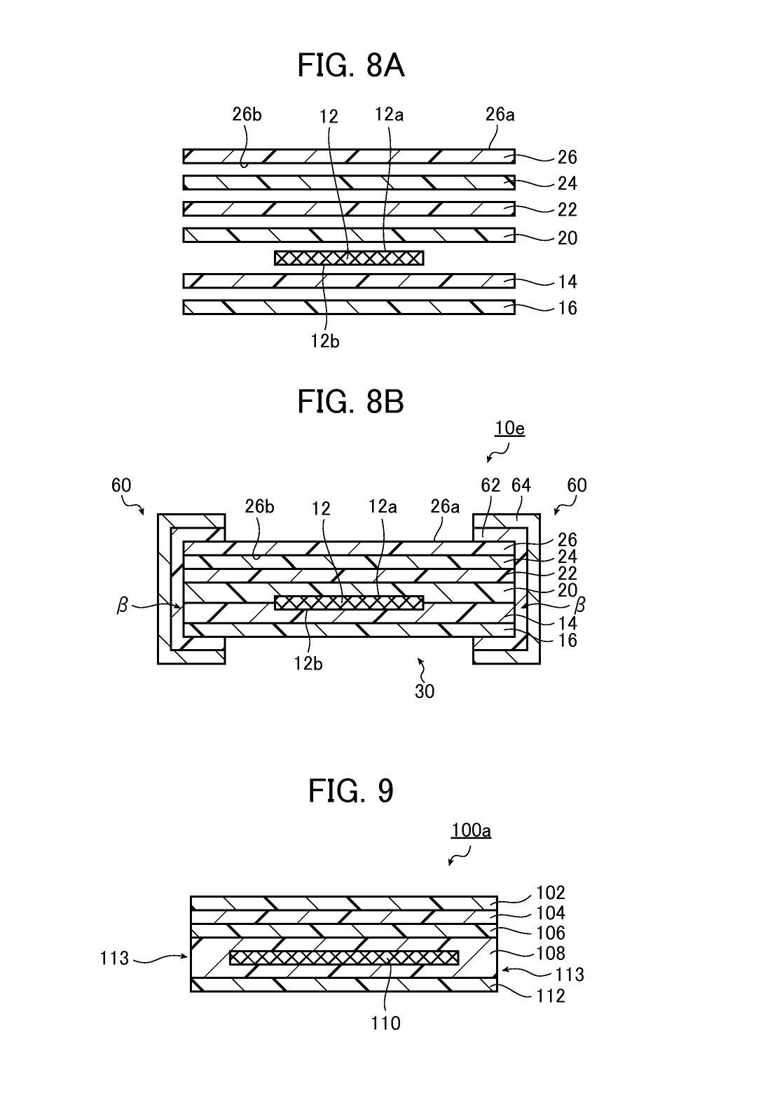

FIG. 8A is a schematic sectional view showing the arrangement state of respective members before vacuum lamination of a solar cell module according to a sixth embodiment of the invention, and FIG. 8B is a schematic sectional view showing the solar cell module according to the sixth embodiment of the invention.

In this embodiment, the same constituent parts as those in the solar cell module 10c of the fourth embodiment shown in FIGS. 6A and 6B are represented by the same reference numerals, and detailed description thereof will not be repeated.

As shown in FIG. 8B, a solar cell module 10e of this embodiment is different from the solar cell module 10c of the fourth embodiment (see FIGS. 6A and 6B) in that the solar cell submodule 12 is sealed by the adhesive filler 20 and the second adhesive filler layer 14, no intermediate seal material 18 is provided, and frame members 60 are provided in edge portions β of a solar cell laminate 30 having the solar cell submodule 12, the second adhesive filler layer 14, the back sheet 16, the moisture vapor barrier film 22, the first adhesive filler layer 24, and the front surface protection layer 26. Other parts are the same as those of the solar cell module 10c of the fourth embodiment, thus detailed description thereof will not be repeated.

In the solar cell module 10e of this embodiment, the frame member 60 is provided so as to improve mechanical resistance of the solar cell module 10e, and similarly to the intermediate seal material 18 of the fourth embodiment, to improve moisture diffusion resistance and moisture resistance of the edge portion β. The frame member 60 has an outer edge seal material 62 and an outer frame material 64. The outer edge seal material 62 is provided inside, and the outer frame material 64 is provided outside.

For the outer edge seal material 62, for example, butyl rubber, polyisoprene, polyisobutylene, isoprene, or polyolefin having thermoplasticity is used.

The outer frame material 64 may have a foil shape or a frame shape. The outer frame material 64 may be formed of, for example, aluminum, an aluminum alloy, copper, or a copper alloy. For example, when a metal foil is used as the outer frame material 64, aluminum, an aluminum alloy, copper, or a copper alloy may be used. The thickness of the metal foil is, for example, 50 to 300 μm. The metal foil may have an adhesive material provided in advance.

For the outer frame material 64, a metal foil tape in which a black PET film is bonded to a metal foil may be used from the viewpoint of aesthetics and design of the solar cell module 10e.

When moisture resistance is required, for example, butyl rubber is used for the outer edge seal material 62, and an L-shaped aluminum frame is used for the outer frame material 64.

In the solar cell module 10e of this embodiment, as in the fourth embodiment, the fluorine-based transparent resin film may be provided on the front surface 26a of the front surface protection layer 26.

The solar cell module 10e of this embodiment may be manufactured as follows. First, as in the fourth embodiment, the second adhesive filler layer 14 and the back sheet 16 are laminated and arranged on the back surface 12b of the solar cell submodule 12. Next, as in the fourth embodiment, the adhesive filler 20, the moisture vapor barrier film 22, the first adhesive filler layer 24, and the front surface protection layer 26 are laminated and arranged on the front surface 12a of the solar cell submodule 12. Accordingly, the respective members are laminated and arranged as shown in FIG. 8A. Thereafter, in a state where the respective members are laminated and arranged, as in the fourth embodiment, vacuum lamination is performed under the conditions of, for example, a temperature of 120 to 145° C. and vacuum/press/retention of 15 to 30 minutes in total. Thereby, the solar cell laminate 30 is formed.

Thereafter, the outer edge seal material 62 of the frame member 60 is provided so as to cover the edge portion β of the solar cell laminate 30, a part of the surface of the front surface protection layer 26, and a part of the surface of the back sheet 16. Thereafter, the outer frame material 64 is bonded onto the outer edge seal material 62. Thereby, the solar cell module 10e of this embodiment shown in FIG. 8B is produced.

In this embodiment, as in the fourth embodiment, when producing the solar cell module 10e, the fluorine-based transparent resin film may be laminated and arranged on the front surface 26a of the front surface protection layer 26, and vacuum lamination may be performed in this state, thereby producing a solar cell module.

In the solar cell module 10e of this embodiment, the frame member 60 is provided, whereby it is possible to obtain same effects as the solar cell module 10c of the fourth embodiment. Moreover, it is also possible to improve mechanical resistance, moisture diffusion resistance, and moisture resistance.

The invention basically has the above-described configuration. Although the solar cell module and the method of manufacturing the same according to the invention have been described in detail, the invention is not limited to the foregoing embodiments, and various improvements or alterations may be of course made without departing from the gist of the invention.

### Example 1

Hereinafter, the solar cell module of the invention will be specifically described.

In this example, solar cell modules of Examples 1 to 5 and Comparative Example 1 were produced, and performance thereof was evaluated.

### Example 1

The solar cell module 10 shown in FIGS. 1A and 1B which has a substrate structure and includes the solar cell submodule 12 using a CIGS film as a light absorbing layer was produced.

For the moisture vapor barrier film 22, a film in which a PET film is used as a base material, and an organic film and an inorganic film are laminated on the PET film was used.

For the adhesive filler 20, the first adhesive filler layer 24, and the second adhesive filler layer 14, SOLAR EVA (EVA) manufactured by MITSUI CHEMICALS FABRO, INC. was used.

For the front surface protection layer 26, a polycarbonate sheet having a thickness of 1.5 mm subjected to heat treatment described below was used. The polycarbonate sheet serving as the front surface protection layer 26 was subjected to heat treatment in the air at 130° C. for three hours in advance so as to suppress curvature due to heat shrinkage during the vacuum lamination step. The thermal shrinkage ratio of the polycarbonate sheet after the heat treatment is 0.01%.

For the back sheet 16, RIPREA TFB MD manufactured by LINTEC CORP. was used.

As the intermediate seal material 18, a sheet material of hot-melt butyl rubber (M-155) manufactured by YOKOHAMA RUBBER CO., LTD. was used and clipped in a rectangular shape. The width of the intermediate seal material 18 was 5 mm, and the distance between the outer circumference of the intermediate seal material 18 and the edge portion of the solar cell module 10 was set to 10 mm.

When producing the solar cell module 10 of Example 1, in a state where these materials are laminated and arranged, vacuum lamination was performed using a vacuum laminator having lifting means, an impingement plate, and heating means under the lamination conditions of the temperature of 140° C. and vacuum/press/retention of 20 minutes in total, to produce the solar cell module 10.

### Example 2

The solar cell module 10a shown in FIG. 3 was produced. The same materials as in Example 1 were used excluding the frame member 60.

For the frame member 60, butyl rubber was used as the outer edge seal material 62, and an Al foil tape was used as the outer frame material 64. For butyl rubber, YOKOHAMA rubber M-155P was used.

When producing the solar cell module 10a of Example 2, after the second adhesive filler layer 14 and the back sheet 16 were arranged on the back surface 12b of the solar cell submodule 12; the adhesive filler 20, the moisture vapor barrier film 22, the first adhesive filler layer 24, and the front surface protection layer 26 were arranged on the front surface 12a of the solar cell submodule 12. Thereafter, vacuum lamination was performed under the lamination conditions of temperature of 140° C. and vacuum/press/retention of 20 minutes in total. Thereafter, butyl rubber was melt at 150 to 190° C., applied to the edge portions of the four sides of the laminated structure, the surface of the front surface protection layer, and the surface of the back surface protection layer at a width of 5 to 10 mm from the edge, and then cooled and hardened. Then, an Al foil tape was stuck so as to surround butyl rubber to provide the frame member 60, thereby producing the solar cell module 10a.

### Example 3

The solar cell module 10a shown in FIG. 3 was produced. The same materials as in Example 1 were used excluding the frame member 60. For the frame member 60, a silicone seal material was used as the outer edge seal material 62. For the silicone seal material, a RTV seal material KE-45 manufactured by SHIN-ETSU CHEMICAL CO., LTD. was used. An L-shaped aluminum frame having a groove was used as the outer frame material 64.

When producing the solar cell module 10a of Example 3, as in Example 2, the laminated structure was produced, and then, the four sides of the laminated structure were set in the groove of the aluminum frame in which a silicone seal material had been filled by application in advance, and the aluminum frame was fixed by means of screw fastening. Thereafter, the laminated structure was allowed to stand for seven days at room temperature to harden the silicone seal material and provide the frame member 60, thereby producing the solar cell module 10a.

### Example 4

The solar cell module 10b shown FIG. 5 was produced. The same materials as in Example 1 were used excluding the frame member 60.

In the frame member 60, butyl rubber was used as the outer edge seal material 62, and an L-shaped aluminum frame having a groove was used as the outer frame material 64. For butyl rubber, YOKOHAMA rubber M-155P was used.

When producing the solar cell module 10b of Example 4, vacuum lamination was performed as in Example 1 to produce a solar cell module. Thereafter, butyl rubber was melt at 150 to 190° C., and filled by application in the groove of the L-shaped aluminum frame. Then, the edge portions of the four sides of the solar cell module were inserted into the groove of the aluminum frame and bonded thereto through baking at 90° C. for 30 minutes in a thermostat chamber, and the aluminum frame was fixed by means of screw fastening to attach the frame member 60 to the solar cell module, thereby producing the solar cell module 10b.

### Example 5

The solar cell module 10 shown in FIGS. 1A and 1B was produced. The solar cell module 10 was produced under the same manufacturing condition as in Example 1 using the same materials as in Example 1 except that an acrylic resin sheet having a thickness of 1.5 mm was used for the front surface protection layer 26.

### Example 6

The solar cell module 10 shown in FIGS. 1A and 1B was produced. A polycarbonate sheet having a thickness of 1.5 mm was used for the front surface protection layer 26, and corona treatment was performed on the surface of the polycarbonate sheet under the conditions of 150 W and 0.5 m/minute, thereby making the surface hydrophilic. Thereafter, the solar cell module 10 was produced under the same manufacturing condition as in Example 1 using the same materials as in Example 1 except that an ETFE film having a thickness of 25 μm was laminated as a fluorine-based transparent resin film on the surface of the polycarbonate sheet through an adhesive filler layer (SOLAR EVA (EVA) manufactured by MITSUI CHEMICALS FABRO, INC.).

### Comparative Example 1

The solar cell module 10 shown in FIG. 1 was produced. The solar cell module 10 was produced under the same manufacturing conditions as in Example 1 using the same materials as in Example 1 except that a FluonETFE film having a thickness of 25 μm manufactured by ASAHI GLASS CO., LTD. was used for the front surface protection layer 26.

### Comparative Example 2

The solar cell module 10 shown in FIG. 1 was produced. A polycarbonate sheet having a thickness of 1.5 mm was used for the front surface protection layer 26. The polycarbonate sheet serving as the front surface protection layer 26 was not subjected to heat treatment in advance, and the thermal shrinkage ratio of the polycarbonate sheet was 0.07%. Otherwise, the solar cell module 10 was produced under the same manufacturing condition as in Example 1 using the same materials as in Example 1 excluding the polycarbonate sheet.

For the six produced solar cell modules, conversion efficiency after a hailstorm fall test and a dump heat test (leaving for 1000 hours under the environment of temperature of 85° C. and humidity of 85 RH %) was measured. The results are shown in Table 2. The hailstorm fall test was executed on the basis of the evaluation criteria of International Standard IEC-61646 10.17 of a thin-film solar cell. The hailstorm fall test and the dump heat test were performed successively.

In the dump heat test, a solar cell module whose conversion efficiency remained equal to or greater than 90% of an initial value was rated A, a solar cell module whose conversion efficiency remained equal to or greater than 80% and smaller than 90% of the initial value was rated B, a solar cell module whose conversion efficiency remained equal to or greater than 60% and smaller than 80% of the initial value was rated C, and a solar cell module whose conversion efficiency remained smaller than 60% of the initial value was rated D.

TABLE 2

| | | Dump Heat Test After |
|---|---|---|
| | Hailstorm Fall Test | Hailstorm Fall Test |
| Example 1 | A | A |
| Example 2 | A | A |
| Example 3 | A | A |
| Example 4 | A | A |
| Example 5 | A | A |
| Example 6 | A | A |
| Comparative Example 1 | B | C |
| Comparative Example 2 | B | D |

Examples 1, 4, 5, and 6 have a structure in which the intermediate seal material which is arranged inside the edge portion is provided, and Examples 2 and 3 have a configuration in which no intermediate seal material is provided and the frame member is provided. As shown in Table 2, in all of Examples 1 to 6, mechanical strength of the front surface protection layer was enhanced, edge portion separation and cavity generation were suppressed, and moisture diffusion from the edge portion was suppressed, thereby suppressing deterioration in conversion efficiency of the solar cell module.

In contrast, in Comparative Example 1, since the film of the front surface protection layer is thin, and the impact strength thereof is weak, in the hailstorm fall test, a satisfactory result was not obtained. Regarding the lowering of the conversion efficiency of the solar cell module, it is considered that this is because cracking occurs in the solar cell submodule itself, the barrier film, or the anodized layer serving as the insulating layer of the substrate due to the hailstorm fall test, and a leak current to the substrate is generated, or, moisture infiltrated from the crackings of the barrier film due to the dump heat test after the hailstorm fall test, and the transparent electrode of the solar cell submodule changed in quality to have higher series resistance.

In Comparative Example 2, when producing the solar cell module, upward concave curvature was generated. In Comparative Example 2, it is considered that a satisfactory result was not obtained for the hailstorm fall test because of the generation of upward concave curvature. Regarding the lowering of the conversion efficiency of the solar cell module, it is considered that this is because moisture infiltrated from a portion where curvature generated due to the dump heat test after the hailstorm fall test, and the transparent electrode of the solar cell submodule is changed in quality to have higher series resistance.

### Example 2

In this example, in order to examine adhesiveness of a solar cell module structure, test structures of Experimental Examples 10 to 13 having a structure of front surface protection layer (polycarbonate)/adhesive filler layer/back surface protection layer (polycarbonate) were produced. The test structures of Experimental Examples 10 to 13 were produced while changing the surface treatment condition of polycarbonate constituting the front surface protection layer, a dump heat test was performed under the conditions of a temperature of 85° C., humidity of 85% RH (relative humidity), and 500 HR (time), and then an adhesion test was performed.

In the test structures of Experimental Examples 10 to 13, polycarbonate was used for the front surface protection layer and the back surface protection layer. For polycarbonate, IUPILON NF-2000 (manufactured by MITSUI GAS CHEMICAL CO., LTD.) having a thickness of 1 mm was used. The test structures of Experimental Examples 10 to 13 have a width of 15 mm and a length of 150 mm.

For the adhesive filler layer, a thermoplastic olefin-based polymer resin seal material Z68 (manufactured by DNP CO., LTD.) was used as olefin (referred to as “olefin” in Table 3), and SOLAR EVA (EVA) manufactured by MITSUI CHEMICALS FABRO, INC. was used as EVA (referred to as “EVA” in Table 3).

A titanate coupling agent 1200 OS (referred to as “primer-A” in Table 3) manufactured by DOW CORNING TORAY CO., LTD. or DY39-067 (referred to as “primer-B” in Table 3) was used as the primer.

In the test structures of Experimental Examples 10 to 13, the polycarbonate sheet which is used for the front surface protection layer was subjected to heat treatment in advance at 125° C. for three hours in the air.

In Experimental Example 10, no primer was applied. In Experimental Example 10, the polycarbonate sheet was not subjected to corona treatment, and the polycarbonate was bonded to the adhesive filler layer using olefin or EVA, thereby obtaining the test structure. In Experimental Example 10, the bonding surface of the polycarbonate sheet to the adhesive filler layer was subjected to corona treatment, and the polycarbonate was bonded to the adhesive filler layer using olefin or EVA, thereby obtaining the test structure.

In regard to the corona treatment, the bonding surface of the polycarbonate sheet to the adhesive filler layer was subjected to the corona treatment using a corona discharger manufactured by KASUGA ELECTRIC WORKS, LTD. under the conditions of a power of 150 W and a processing rate of 0.5 m/minute, thereby making the bonding surface hydrophilic.

In Experimental Example 11, when corona treatment is not performed, a titanate coupling agent 1200 OS (primer-A) manufactured by DOW CORNING TORAY CO., LTD. was penetrated into BEMCOT(registered trademark), applied as a primer to the bonding surface of the polycarbonate sheet to the adhesive filler layer, and dried at room temperature for one hour, and the polycarbonate was then bonded to the adhesive filler layer using olefin or EVA, thereby obtaining the test structure.

In Experimental Example 11, the bonding surface of the polycarbonate sheet to the adhesive filler layer was subjected to the corona treatment under the same conditions as in Experimental Example 10, then, a titanate coupling agent 1200 OS (primer-A) manufactured by DOW CORNING TORAY CO., LTD. was penetrated into BEMCOT(registered trademark), applied as a primer to the bonding surface, and dried at room temperature for one hour, and polycarbonate was then bonded to the adhesive filler layer using olefin or EVA, thereby obtaining the test structure.

In Experimental Example 12, when corona treatment is not performed, a titanate coupling agent DY39-067 (primer-B) manufactured by DOW CORNING TORAY CO., LTD. was penetrated into BEMCOT(registered trademark), applied as a primer to the bonding surface of the polycarbonate sheet to the adhesive filler layer, and dried at room temperature for one hour, and the polycarbonate was then bonded to the adhesive filler layer using olefin or EVA, thereby obtaining the test structure.

In Experimental Example 12, the bonding surface of the polycarbonate sheet to the adhesive filler layer was subjected to the corona treatment under the same conditions as in Experimental Example 10, a titanate coupling agent DY39-067 (primer-B) manufactured by DOWN CORNING TORAY CO., LTD. was penetrated into BEMCOT(registered trademark), applied as a primer to the bonding surface, and dried at room temperature for one hour, and the polycarbonate was then bonded to the adhesive filler layer using olefin or EVA, thereby obtaining the test structure.

In Experimental Example 13, embossing structure was formed in the bonding surface of the polycarbonate sheet to the adhesive filler layer, when corona treatment is not performed, a titanate coupling agent DY39-067 (primer-B) manufactured by DOW CORNING TORAY CO., LTD. was penetrated into BEMCOT(registered trademark), applied as a primer to the bonding surface of the polycarbonate sheet to the adhesive filler layer, and dried at room temperature for one hour, and the polycarbonate was then bonded to the adhesive filler layer using olefin or EVA, thereby obtaining the test structure.

In Experimental Example 13, after embossing structure was formed in the bonding surface of the polycarbonate sheet to the adhesive filler layer, the bonding surface of the polycarbonate sheet to the adhesive filler layer was subjected to the corona treatment under the same conditions as in Experimental Example 10, a titanate coupling agent DY39-067 (primer-B) manufactured by DOW CORNING TORAY CO., LTD. was penetrated into BEMCOT(registered trademark), applied as a primer to the bonding surface, and dried at room temperature for one hour, and the polycarbonate was then bonded to adhesive filler layer using olefin or EVA, thereby obtaining the test structure.

The embossing structure was formed by covering one surface of the polycarbonate sheet with a glass fiber cloth (FGF-400-22 manufactured by CHUKOH CHEMICAL INDUSTRIES, LTD.) and pressing at temperature of 155° C. for 30 minutes using a vacuum laminator.

The test results of the adhesion test of Experimental Examples 10 to 13 are shown in Table 3.

In an adhesion test shown in Table 3, for a laminated test structure of 15 mm×150 mm, upper and lower polycarbonate sheets were tensioned in a direction of 180° at a separation rate of 10 cm/minute by a T-type separation method using a tension tester, and separation strength at this time was measured. In the evaluation of the adhesion test shown in Table 3, separation strength by the adhesion test equal to or greater than 5 N was rated A, separation strength equal to or greater than 2 N and smaller than 5 N was rated B, separation strength equal to or greater than 1 N and smaller than 2 N was rated C, and separation strength equal to or smaller than 1 N was rated D.

TABLE 3

| | | Adhesion Test | | | |
|---|---|---|---|---|---|
| | | No Corona | | Corona Treatment | |
| | | Treatment | | (150 W) | |
| | | EVA | Olefin | EVA | Olefin |
| Experimental | No Primer Applied | D | D | D | D |
| Example 10 | | | | | |
| Experimental | Primer-A Applied | D | D | C | C |
| Example 11 | | | | | |
| Experimental | Primer-B Applied | D | D | C | B |
| Example 12 | | | | | |
| Experimental | Primer-B Applied | D | D | C | A |
| Example 13 | (with Embossing) | | | | |

As shown in Table 3, with primer application and corona treatment, even when polycarbonate is used for the front surface protection layer, it is possible to improve adhesiveness.

### Example 3

In this example, solar cell modules of Examples 10 to 12 and Comparative Examples 10 and 11 were produced, and the performance thereof was evaluated.

### Example 10

The solar cell module 10c shown in FIG. 6B which has a substrate structure and includes the solar cell submodule 12 using a CIGS film as a light absorbing layer was produced.

For the moisture vapor barrier film 22, a film in which a PET film is used as a base material, and an organic film and an inorganic film are laminated on the PET film was used. The moisture vapor barrier film 22 was arranged such that the surface thereof on which the organic layer and the inorganic layer are formed faces the underlying solar cell submodule 12 side so as to prevent moisture diffusion through the base material.

For the first adhesive filler layer 24, a thermoplastic olefin-based polymer resin seal material Z68 (manufactured by DNP CO., LTD.) was used. For the adhesive filler 20 and the second adhesive filler layer 14, SOLAR EVA (EVA) manufactured by MITSUI CHEMICALS FABRO, INC. was used.

For the front surface protection layer 26, a polycarbonate sheet subjected to heat treatment described below was used, and for the polycarbonate sheet, IUPILON NF-2000 (MITSUI GAS CHEMICAL CO., LTD.) having a thickness of 1 mm was used.

The polycarbonate sheet as the front surface protection layer 26 was subjected to heat treatment at 125° C. for three hours in the air in advance so as to suppress curvature due to heat shrinkage during the vacuum lamination step.

Thereafter, corona treatment was performed on the boning surface to the first adhesive filler layer 24. The corona treatment was performed using a corona discharger manufactured by KASUGA ELECTRIC WORKS, LTD. under the conditions of a power of 150 W and the processing rate of 0.5 m/minute, thereby making the bonding surface hydrophilic.

A titanate coupling agent DY39-067 (primer-B) manufactured by DOW CORNING TORAY CO., LTD. was penetrated into BEMCOT(registered trademark), applied to the bonding surface after the corona treatment, and dried at room temperature for one hour.

For the back sheet 16, a three-layered sheet of a back sheet (PVF/Al/PVF) manufactured by MA PACKAGING CO., LTD., an EVA layer, and IUPILON NF-2000NS having a thickness of 0.5 mm was used in order to suppress curvature.

As the intermediate seal material 18, a sheet material of hot-melt butyl rubber (M-155) manufactured by YOKOHAMA RUBBER CO., LTD. was used and clipped in a rectangular shape. The width of the intermediate seal material 18 was 5 mm, and the distance between the outer circumference of the intermediate seal material 18 and the edge portion of the solar cell module 10 was set to 10 mm.

When producing the solar cell module 10c of Example 10, in a state where these materials are laminated and arranged, vacuum lamination was performed using a vacuum laminator having lifting means, an impingement plate, and heating means under the lamination conditions of a temperature of 140° C. and vacuum/press/retention of 20 minutes in total to produce the solar cell module 10c.

### Example 11

The solar cell module 10d shown in FIG. 7B was produced. The same materials as in Example 10 were used except that the intermediate seal material 18 was not provided, and the edge seal material 19 was provided.

For the edge seal material 19, a B-Dry tape having a width of 10 mm manufactured by SAES Getters SpA was used.

When producing the solar cell module 10d of Example 11, the edge seal material 19 was stuck to the front surface protection layer (polycarbonate sheet) in advance, the above respective sheets were laminated inside the front surface protection layer, the laminated structure was temporarily fixed by the tape, and in this state, vacuum lamination was performed using a vacuum laminator having lifting means, an impingement plate, and heating means under the lamination conditions of temperature of 140° C. and vacuum/press/retention of 20 minutes in total to produce the solar cell module 10d.

### Example 12

The solar cell module 10e shown in FIG. 8B was produced. In the solar cell module 10e of Example 12, the intermediate seal material 18 is not provided, and the frame member 60 is provided.

In Example 12, the same materials as in Example 10 were used excluding the frame member 60. For the frame member 60, a silicone seal material was used as the outer edge seal material 62. For the silicone seal material, a RTV seal material KE-45 manufactured by SHIN-ETSU CHEMICAL CO., LTD. was used. An L-shaped aluminum frame having a groove was used for the outer frame material 64.

When producing the solar cell module 10e of Example 12, as in Example 11, a laminated structure was produced, and then, the four sides of the laminated structure were set in the groove of the aluminum frame in which a silicone seal material had been filled by application in advance, and the aluminum frame was fixed by means of screw fastening. Thereafter, the laminated structure was allowed to stand for seven days at room temperature to harden the silicone seal material and provide the frame member 60, thereby producing the solar cell module 10e. (Comparative Example 10)

The solar cell module 10c shown in FIG. 6B was produced. The solar cell module 10c of Comparative Example 10 had the same configuration as Example 10 and produced under the same manufacturing conditions as in Example 10, except that, while the polycarbonate sheet as the front surface protection layer 26 was subjected to heat treatment in advance under the same conditions as in Example 10, corona treatment and primer application were not performed.

### Comparative Example 11

The solar cell module 10d shown in FIG. 7B was produced. The solar cell module 10d of Comparative Example 11 had the same configuration as Example 11 and produced under the same manufacturing conditions as in Example 11, except that, while the polycarbonate sheet as the front surface protection layer 26 was subjected to heat treatment under the same conditions as in Example 10, corona treatment and primer application were not performed.

For the five produced solar cell modules of Examples 10 to 12 and Comparative Examples 10 and 11, conversion efficiency after a dump heat test (leaving for 1000 hours in the environment of temperature of 85° C. and humidity of 85% RH (relative humidity)) was measured. The results are shown in Table 4.

In the dump heat test, the solar cell module whose conversion efficiency remained equal to or greater than 90% of an initial value was rated A, the solar cell module whose conversion efficiency remained equal to or greater than 80% and smaller than 90% of the initial value was rated B, and the solar cell module whose conversion efficiency remained equal to or greater than 60% and smaller than 80% of the initial value was evaluated to be C.

TABLE 4

| | After Dump Heat Test |
|---|---|
| Example 10 | A |
| Example 11 | A |
| Example 12 | A |
| Comparative Example 10 | B |
| Comparative Example 11 | C |

As shown in Table 4, in all of Examples 10 to 12, a satisfactory result was obtained for conversion efficiency after the dump heat test. On the other hand, in Comparative Examples 10 and 11, conversion efficiency was deteriorated after the dump heat test, and a satisfactory result was not obtained.

In Comparative Example 10, separation occurred between the front surface protection layer and the moisture vapor barrier film. However, in regard to moisture diffusion, deterioration was suppressed because the moisture vapor barrier film was provided.

In Comparative Example 11, separation occurred between the front surface protection layer and the moisture vapor barrier film, and the edge seal was also separated. It is estimated therefrom that, in Comparative Example 11, moisture diffusion from the edge occurred to a greater extent than in Comparative Example 10, and thus deterioration was significant.

From the above result, the effects of the invention will become apparent.

What is claimed is:

1. A solar cell module in which a moisture vapor barrier film, a first adhesive filler layer, and a front surface protection layer are laminated on the front surface of a solar cell submodule sealed by an adhesive filler, and a second adhesive filler layer and a back surface protection layer are laminated on a back surface of the solar cell submodule,
wherein the solar cell submodule has a light absorbing layer which is made of a CIGS (copper indium gallium selenide) film, and
wherein, of the front surface protection layer and the back surface protection layer, at least the front surface protection layer is made of a plastic sheet, and the plastic sheet has a thermal shrinkage ratio equal to or smaller than 0.04%.

2. The solar cell module according to claim 1,
wherein the plastic sheet is made of polycarbonate resin or acrylic resin, and the thickness of the plastic sheet is 0.5 to 2.5 mm.

3. The solar cell module according to claim 1,
wherein an intermediate seal material for moisture vapor infiltration prevention is provided within 5 to 30 mm from an edge portion of the back surface protection layer.

4. The solar cell module according to claim 1,
wherein a frame member is provided in the edge portion, the frame member including a seal material provided inside and an outer frame material provided outside, wherein the seal material is made of butyl rubber or silicone resin, and the outer frame material is made of an aluminum frame or a metal foil tape.

5. The solar cell module according to claim 1,
wherein a substrate which is used in the solar cell submodule is an aluminum, a clad material of stainless steel, a clad material of aluminum, or a clad material of aluminum and stainless steel.

6. The solar cell module according to claim 3,
wherein the intermediate seal material is made of butyl rubber, polyisoprene, polyisobutylene, or isoprene.

7. The solar cell module according to claim 1,
wherein a fluorine-based transparent resin film is provided on the front surface protection layer.

8. A method of manufacturing a solar cell module in which a moisture vapor barrier film, a first adhesive filler layer, and a front surface protection layer are laminated on the front surface of a solar cell submodule sealed by an adhesive filler, and a second adhesive filler layer and a back surface protection layer are laminated on the back surface of the solar cell submodule,
wherein the solar cell submodule has a light absorbing layer which is made of a CIGS (Copper indium gallium selenide) film,
of the front surface protection layer and the back surface protection layer, at least the front surface protection layer is made of a plastic sheet,
the method comprising the steps of:
performing heat treatment on the plastic sheet at temperature of 100 to 140° C. in advance;
laminating and arranging the adhesive filler, the moisture vapor barrier film, the first adhesive filler layer, and the plastic sheet subjected to the heat treatment which serves as the front surface protection layer on the front surface of the solar cell submodule, and laminating and arranging the second adhesive filler layer and the back surface protection layer on the back surface of the solar cell submodule; and
performing vacuum lamination in a state where the plurality of layers are laminated and arranged to produce a laminated structure.

9. The method of manufacturing a solar cell module according to claim 8,
wherein, in the lamination and arrangement step, an intermediate seal material for moisture vapor infiltration prevention is further arranged within 5 to 30 mm from an edge portion of the back surface protection layer.

10. The method of manufacturing a solar cell module according to claim 8, further comprising a step of:
providing a frame member with a seal material provided inside and an outer frame material provided outside in the edge portion of the laminated structure, after the vacuum lamination step.

11. The method of manufacturing a solar cell module according to claim 8,
wherein the plastic sheet is made of polycarbonate resin or acrylic resin, and a thickness of the plastic sheet is 0.5 to 2.5 mm.

12. The method of manufacturing a solar cell module according to claim 8,
wherein, in the lamination and arrangement step, a fluorine-based transparent resin film is further arranged on the plastic sheet.

13. A method of manufacturing a solar cell module in which an adhesive filler, a moisture vapor barrier film, a first adhesive filler layer, and a front surface protection layer are laminated on the front surface of a solar cell submodule, and a second adhesive filler layer and a back surface protection layer are laminated on the back surface of the solar cell submodule,
wherein the solar cell submodule has a structure in which a light absorbing layer made of a CIGS (copper indium gallium selenide) film is formed on a substrate in which an anodized aluminum film is formed on the front surface of a metal sheet,
wherein, of the front surface protection layer and the back surface protection layer, at least the front surface protection layer is made of a plastic sheet,
the method comprising the steps of:
performing heat treatment on the plastic sheet in advance;
performing corona treatment on a surface coming in contact with the first adhesive filler layer of the plastic sheet;
coating the corona-treated surface of the plastic sheet with a primer;
laminating and arranging the adhesive filler, the moisture vapor barrier film, and the first adhesive filler layer on the front surface of the solar cell submodule, laminating and arranging the plastic sheet, which is subjected to the heat treatment and the corona treatment and which is coated with the primer, such that the surface with the primer coated faces the first adhesive filler layer, and laminating and arranging the second adhesive filler layer and the back surface protection layer on the back surface of the solar cell submodule; and
performing vacuum lamination in a state where the plurality of layers are laminated and arranged to produce a laminated structure.

14. The method of manufacturing a solar cell module according to claim 13,
wherein the plastic sheet is made of polycarbonate resin or acrylic resin, and the thickness of the plastic sheet is 0.5 to 2.0 mm.

15. The method of manufacturing a solar cell module according to claim 13,
wherein the heat treatment step of the plastic sheet is executed at temperature of 100 to 140° C.

16. The method of manufacturing a solar cell module according to claim 13,
wherein the first adhesive filler layer is made of thermoplastic olefin-based polymer resin or thermoplastic polyurethane resin, and
the temperature of the vacuum lamination step is 120 to 145° C.

17. The method of manufacturing a solar cell module according to claim 13,
wherein the plastic sheet has an embossing structure on the surface which comes in contact with the first adhesive filler layer.

18. The method of manufacturing a solar cell module according to claim 13,
wherein the lamination and arrangement step includes a step of arranging an intermediate seal material for moisture vapor infiltration prevention within 5 to 30 mm from an edge portion of the back surface protection layer.

19. The method of manufacturing a solar cell module according to claim 13,
wherein the lamination and arrangement step includes the step of arranging an edge seal material for moisture vapor infiltration prevention in the edge portions of the front surface protection layer and the back surface protection layer, and laminating and arranging the solar cell submodule, the adhesive filler, the moisture vapor barrier film, the first adhesive filler layer, the plastic sheet, and the second adhesive filler layer inside the edge seal material.

20. The method of manufacturing a solar cell module according to claim 13, further comprising the step of:
providing a frame member equipped with a seal material inside an outer frame material in the edge portion of the laminated structure after the vacuum lamination step.
